(19) United States
(12) Patent Application Publication
(10) Pub. No.: US 2002/0158663 A1
(43) Pub. Date: Oct. 31, 2002

(54) Non-binary digital logic element and circuit design therefor

(76) Inventor: Eliahu Shemesh, Ramat Gan (IL)

Correspondence Address: G.E. EHRLICH (1995) LTD., c/o ANTHONY CASTORINA, SUITE 207, 2001 JEFFERSON DAVIS HIGHWAY, ARLINGTON, VA, 22202, US

(21) Appl. No.: 09/761,662

(22) Filed: Jan. 18, 2001

Related U.S. Application Data
(60) Provisional application No. 60/206,793, filed on May 25, 2000.

(51) Int. Cl. H03K 19/00

(52) U.S. Cl. 326/59

(57) ABSTRACT

Digital logic elements with inputs and outputs capable of assuming three or more logic states are used to implement multi-state logical operations. Definitions are provided for base-3 logic operations such as AND, NOT, and OR, and these definitions are used to derive higher-level logic elements such as flip-flops, latches, and full adders.

### FIELD OF THE INVENTION

The present invention relates to non-binary digital logic elements and the design of circuits therefor.

### BACKGROUND OF THE INVENTION

The computer industry today is based almost exclusively upon binary logic operations and binary circuit elements. In the binary logic system each number is represented as a string of bits, where each bit is capable of assuming one of two states, denoted 0 and 1. Binary logic operations are defined upon inputs and outputs that can assume only two logic levels. Current digital hardware is based upon binary electronic signals, where signals in a circuit have only two possible levels, for example 0 and 5 volts.

The binary system is widespread, but it is an inefficient way to represent numerical information and to perform logic operations. The binary system encodes information in a large number of digits. For example, the decimal system requires only two digits to represent the numbers 0 to 99, whereas the binary system requires seven bits. Conveying binary signals within digital hardware utilizes a large number of data bus wires, and a large number of circuit element inputs. Current technology requires an ever increasing number of inputs to circuit components. As the transistor density in integrated circuits increases, the number of inputs required per circuit increases as well. Integrated circuit manufacturers are seeking ways to increase the available data input. One method currently in use is to multiplex the inputs, so that a single input pin serves a dual purpose. However this method diverts circuit element resources from the primary element function.

Higher state encoding of information is another possible method of reducing hardware wiring and the number of required circuit element inputs. Three-state or trinary logic, for example, can represent the decimal numbers 0 to 242 with only five digits, a substantial improvement over the binary system. Several special purpose trinary logic devices have been developed, however no full logic system has been proposed for non-binary digital logic systems.

Hastings in U.S. Pat. No. 5,610,537 provides a trinary logic input gate in which first output transistor is coupled to a first voltage output to pull the voltage output to a high voltage in response to a voltage input below a defined low threshold. A second output transistor is coupled to a second voltage output and pulls the second voltage output to a low voltage in response to a voltage input above a defined high threshold. Swing limiting circuitry is coupled to the gates of both the first and second output transistors, and when the voltage input is between the defined thresholds, the swing limiting circuitry operates to keep the gates of the first and second output transistors within a middle range of defined thresholds such that both output transistors are enabled, and therefore the first and second voltage outputs are at opposite polarities. When the input voltage is above the high threshold, both outputs are at a low voltage. When the input voltage is below the low threshold, both outputs are at a high voltage. Thus the two voltage outputs can be used to receive and decode three distinct input states at the voltage input.

Mensch Jr. in U.S. Pat. No. 5,212,800 provides a CMOS integrated circuit microcomputer system including circuitry for sensing trinary logic states in a microcomputer by using a tri-state driver circuit connected to both the input and output of a binary latch having only two states. A first trinary logic level is represented by a first logic level produced and maintained on the conductor by the external device, overpowering the binary latch. A second logic state is represented by a second logic level produced and maintained on the conductor by the external device. A third trinary state is represented by an off condition of the tri-state driver, in which case the binary latch holds whatever state is produced by the microcomputer of the connector.

Costello in U.S. Pat. No. 4,860,309 describes a trinary bus communication system, in which trinary digital information is communicated over a pair of electrically conductive lines terminated line to line at least one extremity by an impedance which generally matches the characteristic impedance of the two lines with respect to each other. One or more transmitters in electrical communication with the two lines selectively impose a first potential difference, a second potential difference distinct from the first, or no potential difference across the lines. One or more receivers in electrical communication with the two lines sense the first potential difference and interpret that as a first logical state, sense the second potential difference and interpret that as a second logical state, and sense no potential difference across the two lines and interpret that as a third logical state.

Lasher et. al. in U.S. Pat. No. 4,863,247 presents optical architectures for performing fully parallel, carry-free computation with a trinary, modified signed-digit number representation to allow addition, subtraction and multiplication. Two different optical schemes involving position and polarization encoding enable the fabrication of modular trinary logic systems that accommodate trinary numbers of different magnitudes.

Dedic et. al. in U.S. Pat. No. 5,870,052 uses a successive approximation type analog to digital converter (ADC) with repetitive conversion cycles to perform repetitively a series of conversion cycles. A comparator receives an analog input signal and compares it with an analog comparison signal produced by a digital-to-analog converter. A successive-approximation register circuit holds a digital trial signal value and uses it to control the value of the analog comparison signal in each conversion cycle so as to perform up to two comparisons per cycle, thereby to produce digital data that has a first value (“+1”) when the input signal value is greater than a first comparison value and that has a second value (“−1”) when the input signal value is less than a second comparison value and that in all other cases has a third value (“0”). Such an ADC can employ the same analog circuits as a conventional successive-approximation ADC but can operate at higher speeds because errors in the decisions made in one conversion cycle are, within reasonable limits, corrected automatically in subsequent conversion cycles.

These devices demonstrate that non-binary digital circuitry is technically feasible, but do not provide an overall logical framework that can be used to develop a wide variety of non-binary digital logic devices. Furthermore, these devices do not show how pluralities of these devices may be combined to provide digital processes and the like. A high-level logical system is required to utilize this technology in order to develop base-3 and higher state computers.

### SUMMARY OF THE INVENTION

According to a first aspect of the present invention there is thus provided a digital logic element comprising at least one input and at least one output, each input and each output being capable of assuming a number of logic states, and a logical operation relating said logic states at said input with logic states at said output, and wherein said number of logic states is at least three.

In an embodiment the number of logic states is three, comprising a first state (0), a second state (1), and a third state (2).

In another embodiment the logic states comprise a predetermined set of values of the following types of signals: voltage, current, impedance, nuclear spin, quantum state, polarity, and phase.

In an embodiment of a digital logic operation, the operation has one input (A) and one output (B), and is substantially defined by the following table:

| Input A | Output B |
|---|---|
| 0 | 2 |
| 1 | 0 |
| 2 | 1 |

An element embodying this digital logic operation is insertable into circuitry for use as a NOT gate.

In another embodiment of a digital logic operation, the operation has a first input (A), a second input (B) and an output (C), and is substantially defined by the following table:

| Input A | Input B | Output C |
|---|---|---|
| 0 | 0 | 0 |
| 0 | 1 | 0 |
| 0 | 2 | 0 |
| 1 | 0 | 0 |

| Input A | Input B | Output C |
|---|---|---|
| 1 | 1 | 1 |
| 1 | 2 | 2 |
| 2 | 0 | 0 |
| 2 | 1 | 2 |
| 2 | 2 | 2 |

This digital logic element is insertable into circuitry for use as an AND gate.

In another embodiment of a digital logic operation, the operation has a first input (A), a second input (B) and an output (C), and is substantially defined by the following table:

| Input A | Input B | Output C |
|---|---|---|
| 0 | 0 | 0 |
| 0 | 1 | 1 |
| 0 | 2 | 2 |
| 1 | 0 | 1 |
| 1 | 1 | 1 |
| 1 | 2 | 2 |
| 2 | 0 | 2 |
| 2 | 1 | 2 |
| 2 | 2 | 2 |

An element embodying this digital logic operation is insertable into circuitry for use as an OR gate.

In another embodiment of a digital logic operation, the operation has a first input (A), a second input (B) and an output (C), and is substantially defined by the following table:

| Input A | Input B | Output C |
|---|---|---|
| 0 | 0 | 0 |
| 0 | 1 | 0 |
| 0 | 2 | 0 |
| 1 | 0 | 0 |
| 1 | 1 | 1 |
| 1 | 2 | 1 |
| 2 | 0 | 0 |
| 2 | 1 | 1 |
| 2 | 2 | 2 |

An element embodying this digital logic operation is insertable into circuitry for use as an AND gate.

In another embodiment of a digital logic operation, the operation has a first input (A), a second input (B) and an output (C), and is substantially defined by the following table:

| Input A | Input B | Output C |
|---|---|---|
| 0 | 0 | 0 |
| 0 | 1 | 1 |
| 0 | 2 | 2 |
| 1 | 0 | 1 |
| 1 | 1 | 1 |
| 1 | 2 | 1 |
| 2 | 0 | 2 |

| Input A | Input B | Output C |
|---|---|---|
| 2 | 1 | 1 |
| 2 | 2 | 2 |

An element embodying this digital logic operation is insertable into circuitry for use as an OR gate.

An additional embodiment comprises a programmable logic array operable to implement a truth table involving three logic states.

In another embodiment of a digital logic operation, the operation has a first input (A), a second input (B), a third input (Carryᵢₙ), a first output (Sum), and a second output (Carryₒᵤₜ)), and is substantially defined by the following table:

| Carryᵢₙ | Input A | Input B | Sum | Carryₒᵤₜ |
|---|---|---|---|---|
| 0 | 0 | 0 | 0 | 0 |
| 0 | 0 | 1 | 1 | 0 |
| 0 | 0 | 2 | 2 | 0 |
| 0 | 1 | 0 | 1 | 0 |
| 0 | 1 | 1 | 2 | 0 |
| 0 | 1 | 2 | 0 | 1 |
| 0 | 2 | 0 | 2 | 0 |
| 0 | 2 | 1 | 0 | 1 |
| 0 | 2 | 2 | 1 | 1 |
| 1 | 0 | 0 | 1 | 0 |
| 1 | 0 | 1 | 2 | 0 |
| 1 | 0 | 2 | 0 | 1 |
| 1 | 1 | 0 | 2 | 0 |

| Carryᵢₙ | Input A | Input B | Sum | Carryₒᵤₜ |
|---|---|---|---|---|
| 1 | 1 | 1 | 0 | 1 |
| 1 | 1 | 2 | 1 | 1 |
| 1 | 2 | 0 | 0 | 1 |
| 1 | 2 | 1 | 1 | 1 |
| 1 | 2 | 2 | 2 | 1 |
| 2 | 0 | 0 | 2 | 0 |
| 2 | 0 | 1 | 0 | 1 |
| 2 | 0 | 2 | 1 | 1 |
| 2 | 1 | 0 | 0 | 1 |
| 2 | 1 | 1 | 1 | 1 |
| 2 | 1 | 2 | 2 | 1 |
| 2 | 2 | 0 | 1 | 1 |
| 2 | 2 | 1 | 2 | 1 |
| 2 | 2 | 2 | 0 | 2 |

An element embodying this digital logic operation is insertable into circuitry for use as a full adder.

In another embodiment of a digital logic operation, the operation has a first input (A), a second input (B) and an output (C), and is substantially defined by the following table:

| Input A | Input B | Output C |
|---|---|---|
| 0 | 0 | 2 |
| 0 | 1 | 0 |
| 0 | 2 | 1 |

| Input A | Input B | Output C |
|---|---|---|
| 1 | 0 | 0 |
| 1 | 1 | 0 |
| 1 | 2 | 1 |
| 2 | 0 | 1 |
| 2 | 1 | 1 |
| 2 | 2 | 1 |

An element embodying this digital logic operation is insertable into circuitry for use as a NOR gate.

In another embodiment of a digital logic operation, the operation has a first input (A), a second input (B), a third input (C), a first output (D), a second output (E), and a third output (F), and is substantially defined by the following table:

| | | | Previous | Next |
|---|---|---|---|---|
| | | | Outputs | Outputs |
| Input A | Input B | Input C | (D, E, F) | (D, E, F) |
| 0 | 0 | 0 | (0, 1, 2) | (0, 1, 2) |
| 0 | 0 | 0 | (1, 2, 0) | (1, 2, 0) |
| 0 | 0 | 0 | (2, 0, 1) | (2, 0, 1) |
| 0 | 0 | 1 | (0, 1, 2) | (0, 1, 2) |
| 0 | 0 | 1 | (1, 2, 0) | (1, 2, 0) |
| 0 | 0 | 1 | (2, 0, 1) | (0, 1, 2) |
| 0 | 0 | 2 | | (1, 2, 0) |
| 0 | 1 | 0 | (0, 1, 2) | (0, 1, 2) |
| 0 | 1 | 0 | (1, 2, 0) | (2, 0, 1) |
| 0 | 1 | 0 | (2, 0, 1) | (2, 0, 1) |

| | | | Previous | Next |
|---|---|---|---|---|
| | | | Outputs | Outputs |
| Input A | Input B | Input C | (D, E, F) | (D, E, F) |
| 0 | 1 | 1 | | (0, 1, 2) |
| 0 | 1 | 2 | | (1, 0, 0) |
| 0 | 2 | 0 | | (0, 1, 2) |
| 0 | 2 | 1 | | (0, 1, 2) |
| 0 | 2 | 2 | | (1, 1, 0) |
| 1 | 0 | 0 | (0, 1, 2) | (1, 2, 0) |
| 1 | 0 | 0 | (1, 2, 0) | (1, 2, 0) |
| 1 | 0 | 0 | (2, 0, 1) | (2, 0, 1) |
| 1 | 0 | 1 | | (1, 2, 0) |
| 1 | 0 | 2 | | (1, 2, 0) |
| 1 | 1 | 0 | | (2, 0, 1) |
| 1 | 1 | 1 | | (0, 0, 0) |
| 1 | 1 | 2 | | (1, 0, 0) |
| 1 | 2 | 0 | | (0, 1, 0) |
| 1 | 2 | 1 | | (0, 1, 0) |
| 1 | 2 | 2 | | (1, 1, 0) |
| 2 | 0 | 0 | | (2, 0, 1) |
| 2 | 0 | 1 | | (0, 0, 1) |
| 2 | 0 | 2 | | (1, 0, 1) |
| 2 | 1 | 0 | | (2, 0, 1) |
| 2 | 1 | 1 | | (0, 0, 1) |
| 2 | 1 | 2 | | (1, 0, 1) |

| | | | Previous | Next |
|---|---|---|---|---|
| | | | Outputs | Outputs |
| Input A | Input B | Input C | (D, E, F) | (D, E, F) |
| 2 | 2 | 0 | | (0, 1, 1) |
| 2 | 2 | 1 | | (0, 1, 1) |
| 2 | 2 | 2 | | (1, 1, 1) |

An element embodying this digital logic operation is insertable into circuitry for use as an SR flip-flop.

In another embodiment of a digital logic operation, the operation has a first input (A), a second input (Clock), and one output (Out₁), and is substantially defined by the following table:

| Input A | Clock | Out₁ |
|---|---|---|
| 0 | Trigger | 0 |
| 1 | Trigger | 1 |
| 2 | Trigger | 2 |
| Any value | 0 | Unchanged |

An element embodying this digital logic operation is insertable into circuitry for use as a D flip-flop.

In another embodiment of a digital logic operation, the operation a first input (A), a second input (Clock), a third input (Set₀), a fourth input (Set₁), a fifth input (Set₂), a first output (Out₁), a second output (Out₂), and a third output (Out₃), wherein said second input repetitively undergoes a cycle comprising a first and a second transition, and is substantially defined by the following table:

| Input A | Clock | Out₁ | Out₂ | Out₃ |
|---|---|---|---|---|
| 0 | First | 2 | 0 | 1 |
| | transition | | | |
| 1 | First | 0 | 1 | 2 |
| | transition | | | |
| 2 | First | 1 | 2 | 0 |
| | transition | | | |
| Any value | 0 | Unchanged | Unchanged | Unchanged |

and wherein the value of the outputs can be set while the clock is at 0 by applying signals at Set₀, Set₁, and Set₂, substantially according to the following table:

| Input A | Clock | Set₀ | Set₁ | Set₂ | Out₁ | Out₂ | Out₃ |
|---|---|---|---|---|---|---|---|
| Any value | 0 | 2 | 0 | 0 | 2 | 0 | 1 |
| Any value | 0 | 0 | 2 | 0 | 0 | 1 | 2 |
| Any value | 0 | 0 | 0 | 2 | 1 | 2 | 0 |

An element embodying this digital logic operation is insertable into circuitry for use as a master-slave D flip-flop.

In another embodiment of a digital logic operation, the operation has a first input (A), a second input (Clock), and at least one output (Out₁), wherein the output is changeable only by a predetermined trigger applied to the clock input, said trigger being operable to set the output to the value of said input immediately prior to said trigger. An element embodying this digital logic operation is insertable into circuitry for use as a master-slave D flip-flop.

In another embodiment of a digital logic operation, the operation has a first input (A), a second input (Clock), and one output (Out₁), wherein while said second input is at a predetermined logic state said output is operable to be equal to said first input, and which output is latchable to its current state upon application of a predetermined trigger to said second input, to remain at said current state until said second input returns to said predetermined logic state. An element embodying this digital logic operation is insertable into circuitry for use as a D flip-flop.

In an embodiment of a digital logic operation, the operation has one input (A) and one output (B), and is substantially defined by the following table:

| Input A | Output B |
|---|---|
| 0 | 1 |
| 1 | 2 |
| 2 | 0 |

An element embodying this digital logic operation is insertable into circuitry for use as a NOT gate.

In an embodiment of a digital logic operation, the operation has a first input (A), a second input (B), a third input (C), a first output (D), a second output (E), and a third output (F), wherein if the values of said outputs are at one of a set of predetermined steady states said outputs are latchable to their current states upon application of predetermined logic states to said first, second, and third inputs, to remain at said current states until different logic states are applied to said first, second, and third inputs. An element embodying this digital logic operation is insertable into circuitry for use as an SR flip-flop.

In an embodiment of a digital logic operation, the operation has a first input (A), a second input (B), a third input (C), a fourth input (Clock), a first output (Q1), a second output (Q2), and a third output (Q3), wherein a clock signal varying between a first and a second logic state is applicable to said fourth input, and wherein if the values of said outputs are at one of a set of predetermined steady states said outputs are latchable to their current states upon application of a predetermined trigger to said fourth input, to remain at said states until different logic state are applied to said inputs. An element embodying this digital logic operation is insertable into circuitry for use as a clocked SR flip-flop.

In an embodiment of a digital logic operation, the operation has a first input (Input), which input comprises N digits, Input₁ . . . Input_{N}, a second input (Clock), and an output (Out), which output comprises N digits, Out₁ . . . Out_{N}, and wherein each output digit corresponds to an input digit, wherein all of said inputs and outputs are capable of assuming one of a plurality of logic states, and wherein said second input is operable to undergo a series of transitions, wherein said outputs are changeable only by a predetermined transition of the second input, said transition being operable to set each output digit to the value of its corresponding input digit immediately prior to said transition. An element embodying this digital logic operation is insertable into circuitry for use as a multi-state latch. In another embodiment, each output digit is operable to be equal to its corresponding input digit when said second input is at a predetermined logic state. Another embodiment further comprises a third input (Set), which input comprises a plurality of digits, wherein each digit corresponds to a logic state, and wherein said element is operable to have said N output digits set to a particular logic state when a predetermined signal is applied to the digit of said third input corresponding to said logic state. In another embodiment, the N output digits are setable to a particular logic state when a predetermined signal is applied to said third input only when the second input is at a predetermined state. In another embodiment, the number of logic states that all inputs and all outputs may assume is three. An element embodying this digital logic operation is insertable into circuitry for use as a three-state latch. Another embodiment, further comprises a third input (Set₀), a fourth input (Set₁), and a fifth input (Set₂), wherein the N outputs digits are setable by applying signals to Set₀, Set₁, and Set₂, substantially according to the following table:

| Inputᵢ | | | | Outᵢ |
|---|---|---|---|---|
| i = 1 to N | Set₀ | Set₁ | Set₂ | i = 1 to N |
| Any value | A | A value other | A value other | 0 |
| | | than A | than A | |
| Any value | A value other | A | A value other | 1 |
| | than A | | than A | |
| Any value | A value other | A value other | A | 2 |
| | than A | than A | | |

In a further embodiment, the N output digits are setable to a particular logic state by applying signals at Set₀, Set₁, and Set₂, only when the second input is at a predetermined state.

In an embodiment of a digital logic operation, the operation has a first input (Input), which input comprises N digits, Input₁ . . . Input_{N}, a second input (Clock), a third input (A), a fourth input (Control), and an output (Out), which output comprises N digits, Out₁ . . . Out_{N}, and wherein each output digit corresponds to an input digit, wherein said second input is operable to undergo a series of transitions, wherein said outputs are changeable by a predetermined transition of the second input, wherein if the value of said fourth input equals a first predetermined value said transition is operable shift the output left, if the value of said fourth input equals a second predetermined value said transition is operable to shift the output right, and if the value of said fourth input equals a third predetermined value said transition is operable to latch the output to the value of the input immediately prior to said transition. An element embodying this digital logic operation is insertable into circuitry for use as a multi-state shift register. A further embodiment is operable to shift left, shift right, and latch. Another embodiment, further comprises a fifth input (Set), which input comprises a plurality of digits, wherein each digit corresponds to a logic state, and wherein said element is operable to have the N output digits set to a particular logic state when a predetermined signal is applied to the digit of said fifth input corresponding to said logic state In an additional embodiment, each output digit is operable to be equal to its corresponding input digit when said second input is at a predetermined logic state. In another embodiment, if the input is shifted left the value of Out₁ is operable to be set to a predetermined value, and if the input is shifted right the value of Out_{N} is operable to be set to a predetermined value. In another embodiment, if the input is shifted left the value of Out₁ is operable to be set to the value of the third input immediately prior to said transition, and if the input is shifted right the value of Out_{N} is operable to be set to the value of the third input immediately prior to said transition.

The elements described above may be combined to form more complex elements, such as: additional flip-flop elements, multi-digit full adders, and multi-digit asynchronous counters.

According to a second aspect of the present invention there is thus provided a method for designing a digital logic circuit to implement a truth table, relating the state of at least one input to the state of an output, each input and each output being capable of assuming at least three logic states, comprising a first state (0), a second state (1), and a third state (2), the method comprising:

providing a predetermined truth table having a plurality of rows relating input states to corresponding output states;

identifying each line of the table in which the output state is non-zero;

expressing each thus identified line of the table as a combination of AND and NOT operations on the inputs, so that for the given input values the result of the said operations is the value of the output as given in said table, and for all other input values the result is zero; and,

using said corresponding outputs as inputs to a multi-input OR operation, wherein if all inputs are 0 the output is 0, if the inputs contain 1's but no 2's the output is 1, and if the inputs contain 2's the output is 2, thereby producing a first relationship between said input states and said output states.

In another embodiment, the method further comprises:

reducing the number of inputs and variables in said first relationship by use of at least one of the following logical expressions:

X+X=X,

X*X=X,

X+Y=Y+X,

X*Y=Y*X,

X+0=X,

X*1=X,

X*0=0,

X+2=2,

X*(Y+Z)=X*Y+X*Z,

X*(Y*Z)=(X*Y)*Z,

X+(Y+Z)=(X+Y)+Z,

X*Y+X=X*(Y+1),

X#+Y#+Z#. . . =(X*Y*Z* . . . )#, and

X##*Y##*Z##. . . =(X+Y+Z+. . . )##,

thereby producing a second reduced relationship between said input states and said output states.

In another embodiment, the method further comprises:

reducing the number of inputs and variables in said first relationship by use of at least one of the following logical expressions:

X+X=X,

X*X=X,

X+Y=Y+X,

X*Y=Y*X,

X+0=X,

X*2=X,

X*0=0,

X+1=1,

X*(Y+Z)=X*Y+X*Z,

X*(Y*Z)=(X*Y)*Z,

X+(Y+Z)=(X+Y)+Z,

X*Y+X=X*(Y+2),

X##+Y##+Z## . . . =(X*Y*Z* . . . )##, and

X#*Y#*Z# . . . =(X+Y+Z+ . . .)#,

thereby producing a second reduced relationship between said input states and said output states.

In another embodiment, the step of expressing each said line of the table as a combination of AND and NOT operations on the inputs further comprises:

performing an idXY operation on each said input, wherein X is the input value and Y is the predetermined non-zero output value; wherein the idXY operation is given below:

id01(A)=(2*A)##,

id02(A)=(A#)*(A##),

id11(A)=(2*A#)##,

id12(A)=A*(A##),

id21(A)=(2*A##)##, and

id22(A)=A* A#; and,

using the results of these expressions as inputs to a multi-input AND operation, wherein if any inputs are zero the output is zero, if all inputs are 1 the result is 1, and if all inputs are 2 the output is 2. The idXY operation is defined such that the inputs to the AND operation are preferably identical.

According to a third aspect of the present invention there is thus provided a method for building a digital logic circuit to implement a truth table, relating the state of at least one input to the state of an output, each input and each output being capable of assuming at least three logic states, comprising a first state (0), a second state (1), and a third state (2), the method comprising:

providing a predetermined truth table having a plurality of rows relating input states to corresponding output states;

identifying each line of the table in which the output state is non-zero;

expressing each thus identified line of the table as a combination of AND and NOT operations on the inputs, so that for the given input values the result of the said operations is the value of the output as given in said table, and for all other input values the result is zero;

using said corresponding outputs as inputs to a multi-input OR operation, wherein if all inputs are 0 the output is 0, if the inputs contain l's but no 2's the output is 1, and if the inputs contain 2's the output is 2, thereby producing a first relationship between said input states and said output states; and,

building a 3-state logic circuit by connecting 3-state logic AND, OR, and NOT gates according to said first relationship.

According to a fourth aspect of the present invention there is thus provided a method for building a digital logic circuit to implement a truth table, relating the state of at least one input to the state of an output, each input and each output being capable of assuming at least three logic states, comprising a first state (0), a second state (1), and a third state (2), the method comprising:

providing a predetermined truth table having a plurality of rows relating input states to corresponding output states;

identifying each line of the table in which the output state is non-zero;

expressing each thus identified line of the table as a combination of AND and NOT operations on the inputs, so that for the given input values the result of the said operations is the value of the output as given in said table, and for all other input values the result is zero;

using said corresponding outputs as inputs to a multi-input OR operation, wherein if all inputs are 0 the output is 0, if the inputs contain 1's but no 2's the output is 1, and if the inputs contain 2's the output is 2, thereby producing a first relationship between said input states and said output states;

reducing the number of inputs and variable in the resulting expression by use of at least one of the following logical expressions:

X+X=X,

X*X=X,

X+Y=Y+X,

X*Y=Y*X,

X+0=X,

X*1=X,

X*0=0,

X+2=2,

X*(Y+Z)=X*Y+X*Z,

X*(Y*Z)=(X*Y)*Z,

X+(Y+Z)=(X+Y)+Z,

X*(Y+1)=X*Y+X,

(X*Y*Z* . . . )#=X#+Y#+Z# . . . , and

(X+Y+Z+ . . . )##=X##*Y##*Z## . . . ,

thereby producing a second reduced relationship between said input states and said output states; and,

building a 3-state logic circuit by connecting 3-state logic AND, OR, and NOT gates according to said second relationship.

In another embodiment, the step of expressing each said line of the table as a combination of AND and NOT operations on the inputs further comprises:

performing an idXY operation on each said input, wherein X is the input value and Y is the predetermined non-zero output value; wherein the idXY operation is given below:

id01(A)=(2*A)##,

id02(A)=(A#)*(A##),

id11(A)=(2*A#)##,

id12(A)=A*(A##),

id21(A)=(2*A##)##, and

id22(A)=A*A#; and,

using the results of these expressions as inputs to a multi-input AND operation, wherein if any inputs are zero the output is zero, if all inputs are 1 the result is 1, and if all inputs are 2 the output is 2. The idXY operation is defined such that the inputs to the AND operation are preferably identical.

According to a fifth aspect of the present invention there is thus provided a method for automatically designing a digital logic circuit to implement a truth table, relating the state of at least one input to the state of an output, each input and each output being capable of assuming at least three logic states, comprising a first state (0), a second state (1), and a third state (2), comprising:

providing a predetermined truth table having a plurality of rows relating input states to corresponding output states;

automatically designing a circuit by:

identifying each line of the table in which the output state is non-zero;

expressing each thus identified line of the table as a combination of AND and NOT operations on the inputs, so that for the given input values the result of the said operations is the value of the output as given in said table, and for all other input values the result is zero;

using said corresponding outputs as inputs to a multi-input OR operation, wherein if all inputs are 0 the output is 0, if the inputs contain 1's but no 2's the output is 1, and if the inputs contain 2's the output is 2, thereby producing a first relationship between said input states and said output states; and;

reducing the number of inputs and variable in the resulting expression by use of at least one of the following logical expressions:

X+X=X,

X*X=X,

X+Y=Y+X,

X*Y=Y*X,

X+0=X,

X*1=X,

X*0=0,

X+2=2,

X*(Y+Z)=X*Y+X*Z,

X*(Y*Z)=(X*Y)*Z,

X+(Y+Z)=(X+Y)+Z,

X*Y+X=X*(Y+1),

X#+Y#+Z# . . . =(X*Y*Z* . . . )#, and

X##*Y##*Z## . . . =(X+Y+Z+ . . . )##,

thereby producing a second reduced relationship between said input states and said output states;

simulating the circuit designated by said second relationship; and, verifying that for every combination of inputs the circuit provides the specified output.

According to a sixth aspect of the present invention there is thus provided a method of building non-binary digital circuitry, comprising the steps of:

selecting a base for non-binary digital operation;

defining each of AND, and OR operations in said base;

defining a cyclic NOT operation in said base, wherein if the input to said NOT operation is cyclic the output is cyclic;

testing the system to determine if it possesses at least one of a group of characteristics comprising:

possession of a zero member,

possession of a one member,

obeys the Idempotent Law,

obeys the Law of Commutation, and

obeys the DeMorgan Laws;

if the system does not possess at least one of the characteristics, then redefining said operations until a fit is achieved; and,

building at least one logic gate according to the defined operations.

In a further embodiment, the step of testing the system to determine if it possesses one of a group of characteristics further comprises the step of:

testing said AND, OR, and NOT operations to determine whether they fit at least one of a group of identities comprising:

X+X=X,

X*X=X,

X+Y=Y+X,

X*Y=Y*X,

X+0=X,

X*1=X,

X*0=0, and

X+2=2.

Another embodiment further comprises:

specifying a truth table that provides circuit output values for every combination of input values;

expressing said truth table in terms of said AND, OR, and NOT operations to form an expressed truth table;

reducing said expressed truth table using said characteristics; and,

building said circuitry using said reduced expressed truth table and said gates.

In another embodiment the group of identities further comprises:

X#+Y#+Z# . . . =(X*Y*Z . . . )#, and

X##*Y##+Z## . . . =(X+Y+Z . . . )##.

In another embodiment the group of identities further comprises:

X*(Y+Z)=X*Y+X*Z.

In another embodiment the group of identities further comprises:

X*(Y*Z)=(X*Y)*Z, and

X+(Y+Z)=(X+Y)+Z.

In another embodiment the base of the digital operation is three. In another embodiment the base of the digital operation is greater than three. In an additional embodiment the step of expressing said predetermined truth table in terms of said operations to form an expressed truth table further comprises:

defining an idXY operation, wherein X and Y represent logic states under the base for digital operation, and wherein the output is logic state Y if the input is logic state X, and the output is logic state 0 if the input is not logic state X;

identifying every combination of inputs which yields a non-zero output in said truth table;

for each line of the truth table thus identified, expressing said line to form an expressed line by expressing each line as a series of idXY operations on each expression and performing a multi-input AND operation between all said idXY expressions; and,

performing a multi-input OR operation between all said expressed lines of the truth table.

According to a seventh aspect of the present invention there is thus provided a method of building a digital logic circuit to implement a truth table, relating the state of at least one input to the state of an output, each input and each output being capable of assuming at least three logic states, comprising a first state (0), a second state (1), and a third state (2), the method comprising:

providing a predetermined truth table having a plurality of rows relating input states to corresponding output states;

identifying each line of the table in which the output state is non-zero;

expressing each thus identified line of the table as a combination of AND and NOT operations on the inputs, so that for the given input values the result of the said operations is the value of the output as given in said table, and for all other input values the result is zero;

using said corresponding outputs as inputs to a multi-input OR operation, wherein if all inputs are 0 the output is 0, if the inputs contain l's but no 2's the output is 1, and if the inputs contain 2's the output is 2, thereby producing a first relationship between said input states and said output states;

reducing the number of inputs and variable in the resulting expression by use of at least one of the following characteristics:

possession of a zero member,

possession of a one member,

the Idempotent Law,

the Associative Law,

the Identity Laws,

the Dominance Laws,

the Complement Laws,

the Distributive Law,

the Commutative Law, and

the DeMorgan Laws,

thereby producing a second reduced relationship between said input states and said output states; and,

building a 3-state logic circuit by connecting 3-state logic AND, OR, and NOT gates according to said second relationship.

According to an eighth aspect of the present invention there is thus provided a method for automatically designing a digital logic circuit to implement a truth table, relating the state of at least one input to the state of an output, each input and each output being capable of assuming at least three logic states, comprising a first state (0), a second state (1), and a third state (2), comprising:

providing a predetermined truth table having a plurality of rows relating input states to corresponding output states;

automatically designing a circuit by:

identifying each line of the table in which the output state is non-zero;

expressing each thus identified line of the table as a combination of AND and NOT operations on the inputs, so that for the given input values the result of the said operations is the value of the output as given in said table, and for all other input values the result is zero;

using said corresponding outputs as inputs to a multi-input OR operation, wherein if all inputs are 0 the output is 0, if the inputs contain 1's but no 2's the output is 1, and if the inputs contain 2's the output is 2, thereby producing a first relationship between said input states and said output states; and;

reducing the number of inputs and variable in the resulting expression by use of at least one of the following characteristics:

possession of a zero member,

possession of a one member,

the Idempotent Law,

the Associative Law,

the Identity Laws,

the Dominance Laws,

the Complement Laws,

the Distributive Law,

the Commutative Law, and

the DeMorgan Laws,

thereby producing a second reduced relationship between said input states and said output states;

simulating the circuit designated by said second relationship; and, verifying that for every combination of inputs the circuit provides the specified output.

The terms 3-state logic, base-3 logic, and trinary logic are used interchangeably to mean a digital logic system based upon symbols whose value can be one of a set of three possible logic levels, denoted {0,1,2}. Logic operations are defined upon these symbols to provide a complete logical system. Likewise, the terms n-state logic, base-n logic, and n-ary logic are used interchangeably to mean a digital logic system based upon symbols whose value can be one of a set of n possible logic levels, and should be understood in the same way.

### BRIEF DESCRIPTION OF THE DRAWINGS

For a better understanding of the invention and to show how the same may be carried into effect, reference will now be made, purely by way of example, to the accompanying drawings, in which:

FIG. 1 is a gate-level block diagram showing a simplified 3-state NOT gate.

FIG. 2 is a gate-level block diagram showing a simplified 3-state AND gate.

FIG. 3 is a gate-level block diagram showing a simplified 3-state OR gate.

FIG. 4a is a gate-level block diagram showing a simplified 4-state multi-input OR gate.

FIG. 4b is a gate-level block diagram showing a simplified 3-state multi-input OR gate.

FIG. 5 is a gate-level block diagram showing a simplified 3-state full adder.

FIG. 6 is a gate-level block diagram showing a simplified 3-state multi-digit full adder.

FIG. 7 is a gate-level block diagram showing a simplified 3-state SR flip-flop.

FIG. 8 is a gate-level block diagram showing a simplified 3-state clocked SR flip-flop.

FIG. 9 is a gate-level block diagram showing a simplified 3-state D flip-flop.

FIGS. 10a and 10b are gate-level block diagrams of a simplified 3-state master-slave D flip-flop.

FIG. 11a is a gate-level block diagram showing a simplified 3-state multi-digit asynchronous counter.

FIG. 11b is a simplified waveform diagram showing the outputs of two successive 3-state multi-digit asynchronous counter stages.

FIG. 12 is a gate-level block diagram showing a simplified multi-state latch.

FIG. 13 is a gate-level block diagram showing a simplified multi-state shift register.

FIG. 14 is a block diagram of a simplified method for designing and building non-binary digital logic gates.

FIG. 15 is a block diagram of a simplified method for designing and building non-binary digital logic devices that conform to an arbitrary truth table.

### DESCRIPTION OF THE PREFERRED EMBODIMENTS

Digital logic systems perform logic operations upon variables that assume values from a predetermined group of symbols. Generally, digital computing uses the binary system because design issues are well understood, but, as mentioned above, it has disadvantages in that it necessitates storing and operating upon a large number of variables, and also requires many digits to represent numerical values. This leads to complex wiring and other circuit design problems. Higher-level logic systems overcome these problems, and embodiments of the present invention provide systems that include basic logic elements, and allow them to be combined to form more complex logic devices. As mentioned above, high-level logic systems have not been widely used because it has been difficult to apply design rules similar to those that make binary circuit construction relatively simple. This embodiment presents a method for designing high-level logic circuits by defining a fundamental set of logic operations, examining the logic system defined by these operations for higher level behavior, and then designing devices conforming to any desired truth table based upon this fundamental set of logic operations. This method is described below in more detail.

A base-3 logic system, for example, defines logical operations on a set of three symbols {0,1,2}. This is analogous to the binary system, which defines logical operations upon a set of two symbols {0,1}. The three basic logic operations are NOT, AND, and OR. These operations are defined by means of truth tables, which define the relationship between the inputs and the outputs. Higher level relationships are derived from these basic logic operations. In the following embodiment, logic devices, such as simple logic gates, flip-flops and counters, are developed for base-3 logic. These devices are similar in function to existing binary logic devices. These logical relationships and devices may be used to develop base-3 logic computers and compatible programming languages.

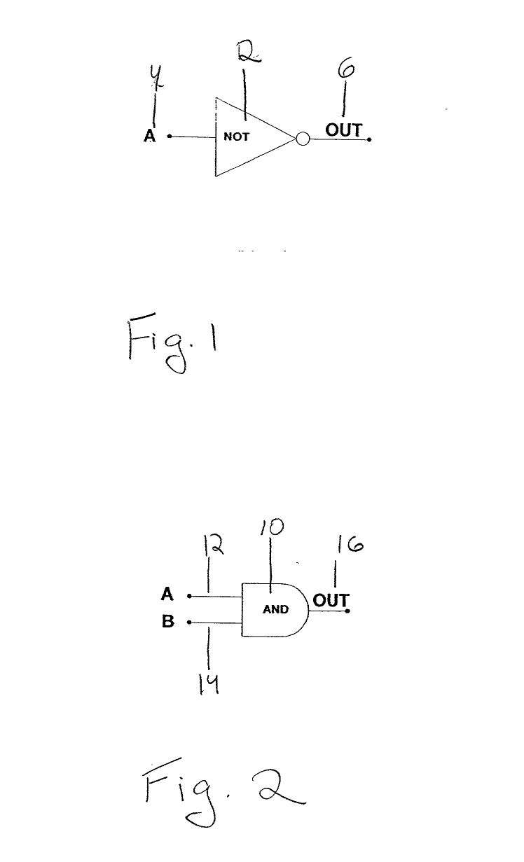

Reference is now made to FIG. 1, which shows the schematic symbol of a NOT gate 2. The NOT gate 2 has one input 4 and one output 6. The mathematical symbol for the NOT operation, as used herein, is #.

Reference is now made to FIG. 2, which shows the schematic symbol of an AND gate 10. The AND gate 10 has two inputs A 12 and B 14, and one output 16. The mathematical symbol for the AND operation, as used herein, is *.

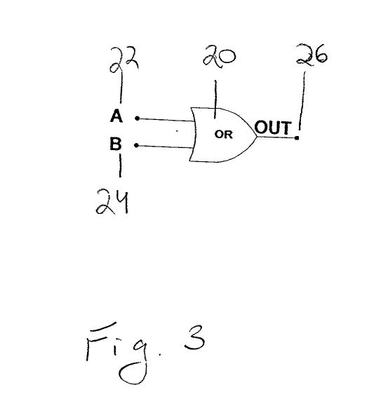

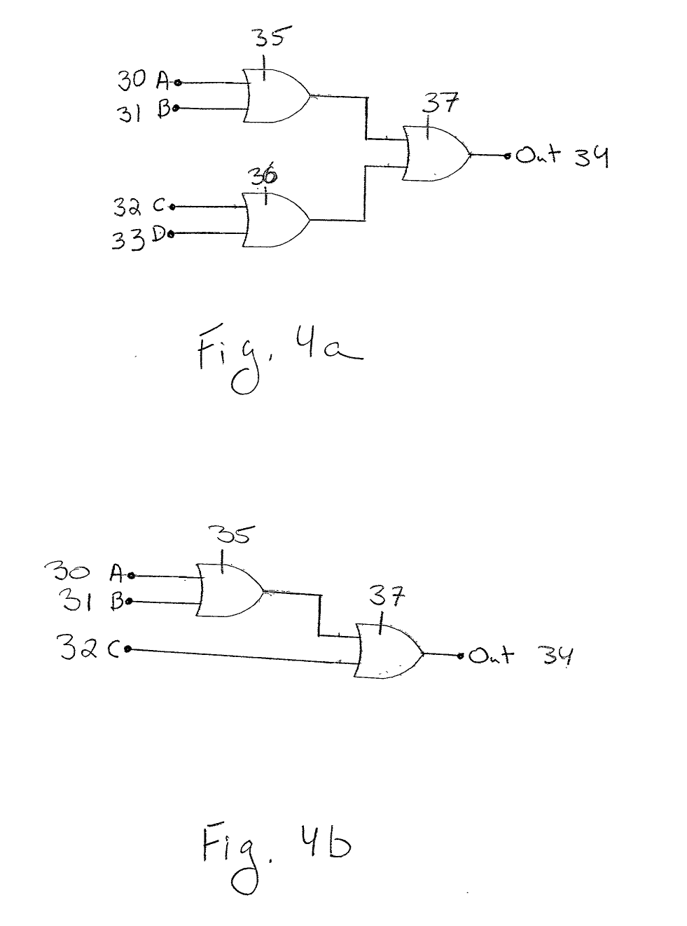

Reference is now made to FIG. 3, which shows the schematic symbol of an OR gate 20. The OR gate 20 has two inputs A 22 and B 24, and one output 26. The mathematical symbol for the OR, as used herein, operation is +.

It is noted that, where appropriate, the + symbol is used in this document to denote mathematical addition, as well as the logical OR. The skilled person will distinguish the correct meaning from the context.

A difficulty with non-binary digital logic is to assign a meaning to each of the basic logic operations mentioned above. The definition of the three basic logic operations determines the higher level behavior of the logic system. A first preferred embodiment defines these operations as described below.

The truth table for the NOT operation is given in Table 1.

TABLE 1
The NOT Operation

| A | A# | A## |
|---|---|---|
| 0 | 2 | 1 |
| 1 | 0 | 2 |
| 2 | 1 | 0 |

It is seen from Table 1 that the NOT gate 2 is cyclic, in that given a cyclic input the NOT gate produces a cyclic output. If the input A 4 to the device is (0,1,2) the gate output 6 is given by column A# and is (2,0,1). An alternate embodiment of the NOT gate provides the output shown in column A##, and is a cyclic output in the reverse direction. That is, an input of (0,1,2) produces an output of (1,2,0). This alternate embodiment is equivalent to connecting two NOT gates in succession, shown as X# in Table 1. The examples given below are derived from the first definition for X#.

One embodiment of the NOT gate may be provided by combining two simply implemented functions together to create the NOT operation. This embodiment is illustrated in the following table:

| A | f₁(A) | f₂(A) | f₁(A) OR f₂(A) |
|---|---|---|---|
| 0 | 2 | 0 | 2 |
| 1 | 0 | 0 | 0 |
| 2 | 0 | 1 | 1 |

Combining the results of these two functions together with an OR operation (defined below) is equivalent to performing the NOT operation. This embodiment is advantageous for certain hardware implementations.

An additional embodiment of the NOT operation is given in the table below.

| A | A# |
|---|---|
| 0 | 1 |
| 1 | 2 |
| 2 | 0 |

This embodiment provides an alternate definition for a cyclic NOT. This embodiment is equivalent to the A## operation defined in Table 1 above.

In the present embodiment a 2-input AND operation is defined by Table 2.

TABLE 2
The AND Operation

| A | B | A * B |
|---|---|---|
| 0 | 0 | 0 |
| 0 | 1 | 0 |
| 0 | 2 | 0 |
| 1 | 0 | 0 |
| 1 | 1 | 1 |
| 1 | 2 | 2 |
| 2 | 0 | 0 |
| 2 | 1 | 2 |
| 2 | 2 | 2 |

In the present embodiment a 2-input OR operation is Table 3.

TABLE 3
The OR Operation

| A | B | A + B |
|---|---|---|
| 0 | 0 | 0 |
| 0 | 1 | 1 |
| 0 | 2 | 2 |
| 1 | 0 | 1 |
| 1 | 1 | 1 |
| 1 | 2 | 2 |
| 2 | 0 | 2 |
| 2 | 1 | 2 |
| 2 | 2 | 2 |

Reference is now made to FIG. 4a that shows how a four-input OR gate may be constructed from three two-input OR gates. The four-input OR gate has inputs A 30, B 31, C 32, and D 33, one output 34, and comprises three two-input OR gates 35, 36, and 37 connected such that the inputs are connected in pairs to OR gates 35 and 36. Thus, inputs A 30 and B 31 are the inputs to OR gate 35, and inputs C 32 and D 33 are the inputs to OR gate 36. The outputs of OR gates 35 and 36 are connected as inputs to OR gate 37. The output of OR gate 37 is the multiple OR gate output 34.

Reference is now made to FIG. 4b that shows how a three-input OR gate may be constructed from two two-input OR gates. Parts that are identical to those in FIG. 4a are given the same reference numerals and are not referred to again except as necessary for an understanding of the present embodiment. The three-input OR gate has inputs A 30, B 31, and C 32, one output 34, and two OR gates 35, and 37 connected such that inputs A 30 and B 31 are connected to OR gate 35 and the remaining input C 32 and the output of OR gate 35 are input directly into the next stage, OR gate 37.

As the skilled person will appreciate, the architectures shown in FIGS. 4a and 4b can be expanded to provide gates having any number of logic inputs, odd or even. The resulting multiple-input OR has the following output. If one or more of the inputs are 2, the output is 2. If the inputs are any combination of 0's and 1's, the output is 1. If the inputs are all 0's, the output is 0.

An advantage of the above-defined gates is that they provide a logic system that observes the following mathematical identities:

| Rule No. | Rule | Rule Name |
|---|---|---|
| 1. | X## = (X#)# | |
| 2. | X### = X | Triple Complement Law |
| 3. | X + Y = Y + X | Commutative Law |
| | X * Y = Y * X | |
| 4. | (X + Y) + Z = X + (Y + Z) | Associative Law |
| | (X * Y) * Z = X * (Y * Z) | |
| 5. | X + 0 = X | Identity Laws |
| | X * 1 = X | |
| 6. | X + 2 = 2 | Dominance Laws |
| | X * 0 = 0 | |
| 7. | X + X = X | Idempotent Laws |
| | X * X = X | |
| 8. | X + X# + X## = 2 | Complement Laws |
| | X * X# * X## = 0 | |

| Rule No. | Rule | Rule Name |
|---|---|---|
| 9. | X * (Y + Z) = X * Y + X * Z | Distributive Law |
| 10. | X * Y + X = X * (Y + 1) | |
| 11. | X# + Y# + Z# . . . = | Demorgan's Laws |
| | (X * Y * Z * . . . )# | |
| | X## * Y## * Z## . . . = | |
| | (X + Y + Z + . . . )## | |
| 12. | X + (Y#) = X + Y# | |
| | X * (Y#) = X * Y# | |
| 13. | X + ((Y#)#) = X + Y## | |
| | X * ((Y#)#) = X * Y## | |
| 14. | (X#) + Y = X# + Y | |
| | (X#) * Y = X# * Y | |
| 15. | ((X#)#) + Y = X## + Y | |
| | ((X#)#) * Y = X## * Y | |
| 16. | (X + Y) + Z = X + Y + Z | |

These identities are useful for analyzing and simplifying circuit design in this embodiment of a base-3 logic system. In particular, rule 10 is used to eliminate variables from logic equations. Such identities have long been used to simplify circuit design in binary logic. An inability to apply them to non-binary digital logic has made it difficult to design circuitry using such logic. However, the above definitions allow the identities to be applied to non-binary logic as shown.

Furthermore, in the above embodiment, a three's complement representation, similar to the two's complement representation of the binary logic system, may provide a simple method for representing negative numbers and performing subtraction. In this representation, an additional digit representing the sign of the number precedes each number. Positive numbers are preceded by a 0, and negative numbers are preceded by a 2. A number is converted to the opposite sign by performing the complement function, c(X), on the number bit-by-bit and then adding 1.

−T=c(T)+1

A truth table for the complement operation is given in Table 4.

TABLE 4
The Complement Operation

| A | c(A) |
|---|---|
| 0 | 2 |
| 1 | 1 |
| 2 | 0 |

The complement function is defined by the following logic expression:

c(X)=X#*X##+(2*X#)##

Using this representation, subtraction is easily performed by adding a negative number. For example:

T=00121

−T=c(00121)+1=22101+1=22102

T−T=T+(−T)=00121+22102=00000

Note that only a fixed number of digits participate in mathematical operations performed under this representation. In the previous example, the number, T, is represented by five digits. During the final addition operation a sixth carry digit is produced. This sixth digit is discarded, and the result of the operation is a five digit number.

When performing arithmetic operations other than subtraction using complement notation, the digit presenting the sign of the number does not participate in number manipulation. For example, during multiplication the numbers are multiplied without the sign digit, and then the correct sign digit is added to the number.

An additional operation that may be defined for the logic system of the present embodiment is “Identifying the Variable”. This operation is used to isolate a variable, so that the logic output is set to a predetermined value if the input is at the desired logic level. If the input is not at the desired logic level, the variable is set to 0. For example, the operation id01(X) outputs 1 if the input is 0, but outputs 0 for an input of 1 or 2. This operation is defined in the following truth table:

TABLE 5
The Identifying the Variable Operation

| A | id01(A) | id02(A) | id11(A) | id12(A) | id21(A) | id22(A) |
|---|---|---|---|---|---|---|
| 0 | 1 | 2 | 0 | 0 | 0 | 0 |
| 1 | 0 | 0 | 1 | 2 | 0 | 0 |
| 2 | 0 | 0 | 0 | 0 | 1 | 2 |

The logical relationship for these operations is shown below:

id01(A)=(2*A)##

id02(A)=(A#)*(A##)

id11(A)=(2*A#)##

id12(A)=A*(A##)

id21(A)=(2*A##)##

id22(A)=A*A#

The “Identifying the Variable” operation is useful for expressing an arbitrary truth table in terms of the basic logic operations, as a sum of the products representation. Once a truth table has been expressed using the “Identifying the Variable”, the mathematical identities observed by this logic system are used to simplify this expression where possible. An example of the sum of the products representation is given below for a full adder. It can be used to implement any truth table in the base-3 system of the present embodiment.

A NOR operation may be defined according to the above definitions of the OR and NOT logic operations. The NOR gate is formed by connecting the output of an OR gate to a NOT gate, thereby obtaining the following truth table:

TABLE 6
The NOR Operation

| Input A | Input B | Output |
|---|---|---|
| 0 | 0 | 2 |
| 0 | 1 | 0 |
| 0 | 2 | 1 |
| 1 | 0 | 0 |
| 1 | 1 | 0 |
| 1 | 2 | 1 |
| 2 | 0 | 1 |
| 2 | 1 | 1 |
| 2 | 2 | 1 |

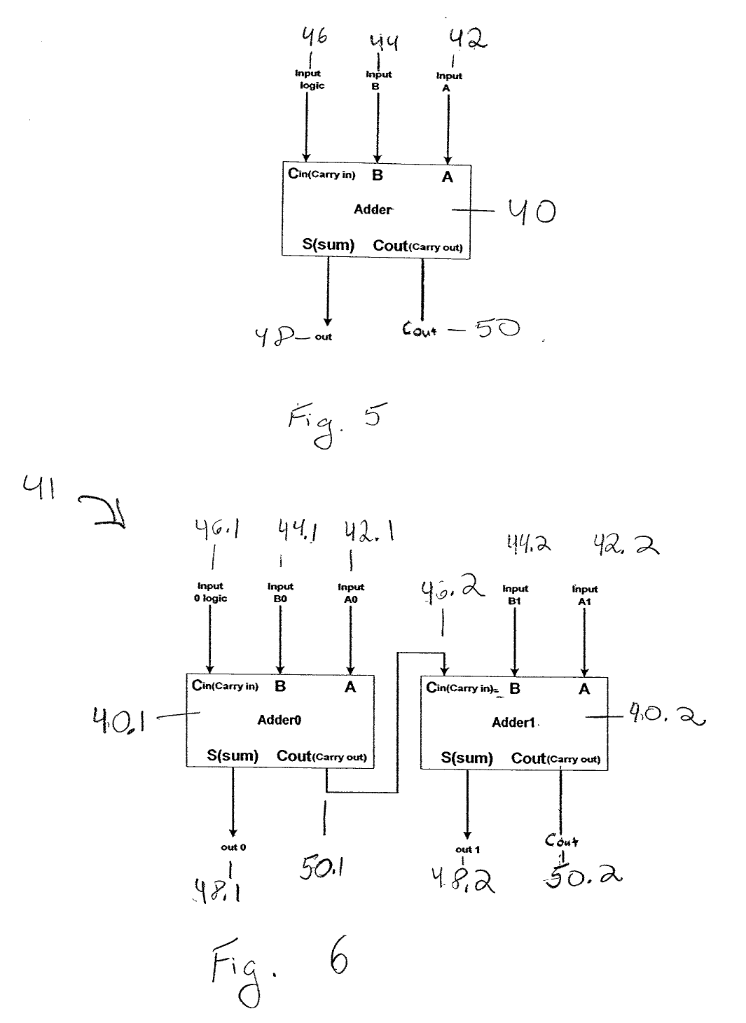

Reference is now made to FIG. 5, which provides a simplified illustration of a full adder 40. The full adder 40 has two logic inputs A 42 and B 44, a Carryᵢₙ input 46, a Sum output 48 and a Carryₒᵤₜ output 50. The Carryᵢₙ input 46 and Carryₒᵤₜ output 50 are for chaining to other full adders to create a multi-digit adder, as will be described in more detail below. The truth table for the full adder is as follows.

TABLE 7
The Full Adder

| Line No. | Carryᵢₙ | Input A | Input B | Sum | Carryₒᵤₜ |
|---|---|---|---|---|---|
| 1 | 0 | 0 | 0 | 0 | 0 |
| 2 | 0 | 0 | 1 | 1 | 0 |
| 3 | 0 | 0 | 2 | 2 | 0 |
| 4 | 0 | 1 | 0 | 1 | 0 |
| 5 | 0 | 1 | 1 | 2 | 0 |
| 6 | 0 | 1 | 2 | 0 | 1 |
| 7 | 0 | 2 | 0 | 2 | 0 |
| 8 | 0 | 2 | 1 | 0 | 1 |
| 9 | 0 | 2 | 2 | 1 | 1 |
| 10 | 1 | 0 | 0 | 1 | 0 |
| 11 | 1 | 0 | 1 | 2 | 0 |
| 12 | 1 | 0 | 2 | 0 | 1 |
| 13 | 1 | 1 | 0 | 2 | 0 |
| 14 | 1 | 1 | 1 | 0 | 1 |
| 15 | 1 | 1 | 2 | 1 | 1 |
| 16 | 1 | 2 | 0 | 0 | 1 |
| 17 | 1 | 2 | 1 | 1 | 1 |
| 18 | 1 | 2 | 2 | 2 | 1 |
| 19 | 2 | 0 | 0 | 2 | 0 |
| 20 | 2 | 0 | 1 | 0 | 1 |
| 21 | 2 | 0 | 2 | 1 | 1 |
| 22 | 2 | 1 | 0 | 0 | 1 |
| 23 | 2 | 1 | 1 | 1 | 1 |
| 24 | 2 | 1 | 2 | 2 | 1 |
| 25 | 2 | 2 | 0 | 1 | 1 |
| 26 | 2 | 2 | 1 | 2 | 1 |
| 27 | 2 | 2 | 2 | 0 | 2 |

The full adder 40 may be expressed as a combination of the basic logic operations by a procedure denoted forming the sum of the products. The identifier operation is useful for this procedure. Consider line 6 in Table 7. Carryₒᵤₜ for this line can be expressed in terms of the inputs A, B, and Carryᵢₙ as follows:

Carryₒᵤₜ=id01(Carryᵢₙ)* id11(A)*id21(B)

The output of this expression is 1 only for the inputs given on line 6 of the above table. Any other values for the inputs give a result of 0. Using the definitions for the id function gives:

Carryₒᵤₜ=(2*Carryᵢₙ)##*(2*A#)##(2*B##)##

Each line of table in which Carryₒᵤₜ has a non-zero value is expressed in this manner. The results of these expressions serve as the inputs to a multi-input OR operation. The output of the OR operation is a complete expression of the value of Carryₒᵤₜ as a function of the inputs.

An expression for the Sum output is obtained in the same manner. A complete definition of the Sum output in terms of the three basic logic operations is:

Sum=(2*Carryᵢₙ)##*(2*A)#*(2*B#)##+Carryᵢₙ#*Carryᵢₙ##*A#*A##*B*B#+(2*Carryᵢₙ)##*(2*A#)##*(2*B)##+Carryᵢₙ#*Carryᵢₙ##*A*A##*B*B##+Carryᵢₙ#*Carryᵢₙ##*A*A#*B#*B##+(2*Carryᵢₙ)##*(2*A##)##(2*B##)##+(2*Carryᵢₙ#)##*(2*A)##*(2*B)##+Carryᵢₙ*Carryᵢₙ##*A#*A##*B*B##+Carryᵢₙ*Carryᵢₙ##*A*A*#*B#*B##+(2*Carryᵢₙ#)##*(2*A#)##*(2*B##)##+(2*Carryᵢₙ#)##*(2*A##)##*(2*B#)##+Carryᵢₙ*Carryᵢₙ##*A*A#*B*B#+Carryᵢₙ*Carryᵢₙ#A#*A##*B#*B##+(2*Carryᵢₙ##)##*(2*A)##(2*B##)##+(2*Carryᵢₙ##)##*(2*A#)##(2*B#)##+Carryᵢₙ*Carryᵢₙ#*A*A##*B*B#+(2*Carryᵢₙ##)##*(2*A##)##*(2*B)##+Carryᵢₙ*Carryᵢₙ#*A*A# B*B##

If possible, this expression may be simplified using the mathematical identities observed by this logic system.

The method described above can be used to implement any arbitrary truth table. For example, it is possible to design a programmable logic array for the present embodiment of a base-3 logic system to produce a device with any desired logical relationship between the inputs and the outputs.

Reference is now made to FIG. 6, which is a simplified illustration of a three-state multi-digit full adder 41. Parts that are identical to those shown in FIG. 5 are given the same reference numerals and are not referred to again except as necessary for an understanding of the present embodiment. The multi-digit full adder 41 is comprised of n full-adders 40.1 . . . 40.n, where in this example n=2. The Carryᵢₙ input of the first stage 46.1 is connected to logic level 0. The Carryₒᵤₜ output 50 of each adder (except the final adder) is connected to the Carryᵢₙ input 46 of the subsequent adder. The inputs, A 42 and B 44, of each adder serve as the multi-digit adder inputs, and the Sum outputs 48 serve as the multi-digit adder outputs, where the first adder in the sequence is the least significant digit and the final adder is the most significant digit.

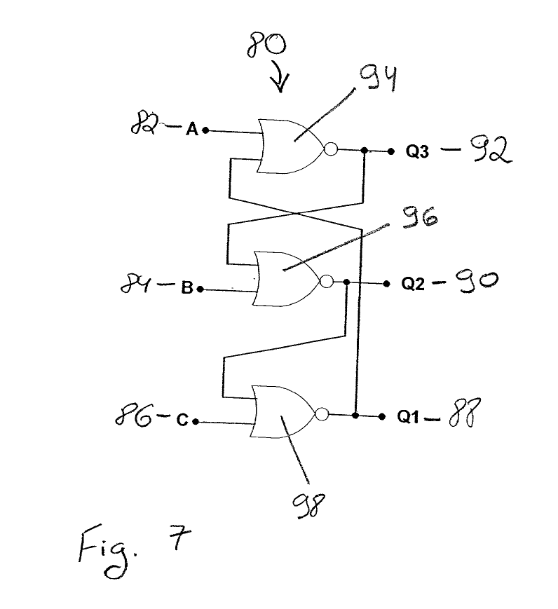

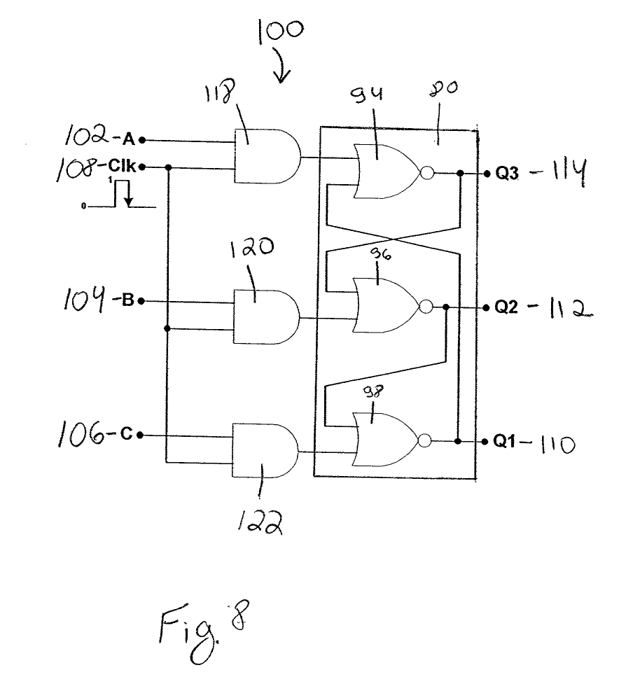

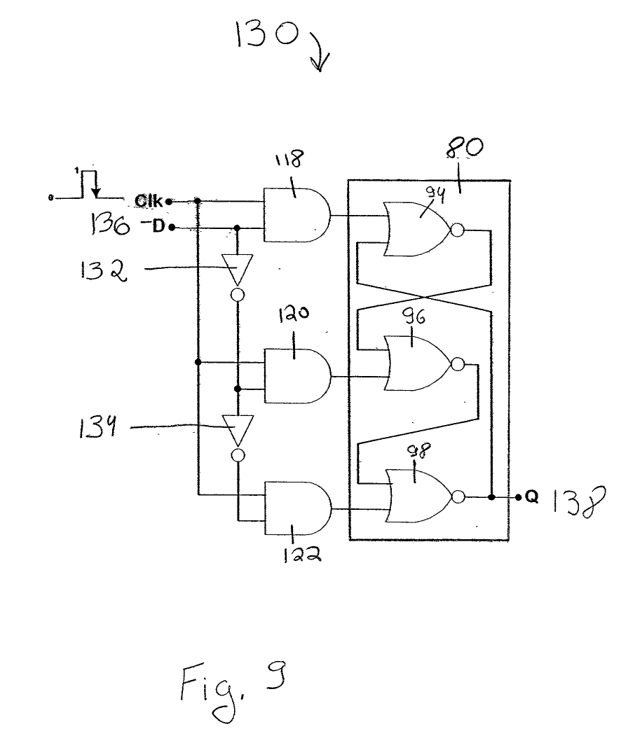

Reference is now made to FIG. 7, which is a simplified illustration of a three-state SR flip-flop. Three-state SR flip-flop 80, comprises three inputs A 82, B 84, and C 86, three outputs Q1 88, Q2 90, and Q3 92, and is made up of three NOR gates 94, 96, and 98. The inputs to NOR gate 94 are logic input A 82 and output Q1 88 from NOR gate 98. The inputs to NOR gate 96 are logic input B 84 and output Q3 92 from NOR gate 94. The inputs to NOR gate 98 are logic input C 86 and output Q2 90 from NOR gate 96. The SR flip-flop output Q1 88 is the output of NOR gate 98. The SR flip-flop output Q2 90 is the output of NOR gate 96. The SR flip-flop output Q3 92 is the output of NOR gate 94.

The SR flip-flop embodied in FIG. 7 has three output steady states (0,1,2), (1,2,0), and (2,0,1). Upon startup the device enters one of these states. Once the device is in one of these states, disconnecting the input, i.e. setting the inputs to (0,0,0), preserves the device in its current state until a different input is applied. This enables the device to function as a memory element, forming the basis for more complex circuit elements required by the computing environment. If the output is not in one of the steady states, disconnecting the input causes it to return unpredictably to one of the steady states. The relationship between the inputs and outputs for this device are shown in Table 8.

TABLE 8
The SR Flip-Flop

| | | | Previous | Next |
|---|---|---|---|---|
| Input A | Input B | Input C | Outputs | Outputs |
| 0 | 0 | 0 | (0, 1, 2) | (0, 1, 2) |
| 0 | 0 | 0 | (1, 2, 0) | (1, 2, 0) |
| 0 | 0 | 0 | (2, 0, 1) | (2, 0, 1) |
| 0 | 0 | 1 | (0, 1, 2) | (0, 1, 2) |
| 0 | 0 | 1 | (1, 2, 0) | (1, 2, 0) |
| 0 | 0 | 1 | (2, 0, 1) | (0, 1, 2) |
| 0 | 0 | 2 | | (1, 2, 0) |
| 0 | 1 | 0 | (0, 1, 2) | (0, 1, 2) |
| 0 | 1 | 0 | (1, 2, 0) | (2, 0, 1) |
| 0 | 1 | 0 | (2, 0, 1) | (2, 0, 1) |
| 0 | 1 | 1 | | (0, 1, 2) |
| 0 | 1 | 2 | | (1, 0, 0) |
| 0 | 2 | 0 | | (0, 1, 2) |
| 0 | 2 | 1 | | (0, 1, 2) |
| 0 | 2 | 2 | | (1, 1, 0) |
| 1 | 0 | 0 | (0, 1, 2) | (1, 2, 0) |
| 1 | 0 | 0 | (1, 2, 0) | (1, 2, 0) |
| 1 | 0 | 0 | (2, 0, 1) | (2, 0, 1) |
| 1 | 0 | 1 | | (1, 2, 0) |
| 1 | 0 | 2 | | (1, 2, 0) |
| 1 | 1 | 0 | | (2, 0, 1) |
| 1 | 1 | 1 | | (0, 0, 0) |
| 1 | 1 | 2 | | (1, 0, 0) |
| 1 | 2 | 0 | | (0, 1, 0) |
| 1 | 2 | 1 | | (0, 1, 0) |
| 1 | 2 | 2 | | (1, 1, 0) |
| 2 | 0 | 0 | | (2, 0, 1) |
| 2 | 0 | 1 | | (0, 0, 1) |
| 2 | 0 | 2 | | (1, 0, 1) |
| 2 | 1 | 0 | | (2, 0, 1) |
| 2 | 1 | 1 | | (0, 0, 1) |
| 2 | 1 | 2 | | (1, 0, 1) |
| 2 | 2 | 0 | | (0, 1, 1) |
| 2 | 2 | 1 | | (0, 1, 1) |
| 2 | 2 | 2 | | (1, 1, 1) |

When no value is stated for the previous output, the device response to the input is independent of the previous state of the device. This device is similar in structure to the binary SR flip-flop. Like the binary SR flip-flop it serves as a basis for development of more complex devices.

Reference is now made to FIG. 8, which is a simplified illustration of a three-state clocked SR flip-flop 100. Parts that are identical to those shown in FIG. 7 are given the same reference numerals and are not referred to again except as necessary for an understanding of the present embodiment. Clocked SR flip-flop 100, comprises three logic inputs A 102, B 104, and C 106, a clock input 108, three logic outputs Q1 110, Q2 112, and Q3 114, and is made up of an SR flip-flop 80 and three AND gates 118, 120, and 122. In the embodiment of FIG. 8 the clock signal is a square wave varying between the 0 and 1 logic levels. Clocked SR flip-flop 100 has the same three steady states as the SR flip-flop in the embodiment of FIG. 7, namely: (0,1,2), (1,2,0), and (2,0,1). Device 100 latches one of the steady states when the clock is at 0. When the clock is 1, the inputs to SR flip-flop 80 are equivalent to the inputs to the clocked SR flip-flop inputs A 102, B 104, and C 106, and the clocked SR flip-flop truth table is equivalent to the SR flip-flop truth table shown in Table 8. When the clock goes to 0 the inputs to the SR flip-flop 80 are (0,0,0). If the clocked SR flip-flop 100 is in one of the steady states, that state is latched. Otherwise, the device unpredictably goes to one of the steady states. The clocked SR flip-flop can alternately be embodied to change state in response to other types of trigger signals, for example a level-triggered clock. The various types of triggers apply to all the following embodiments in which a trigger signal is required.

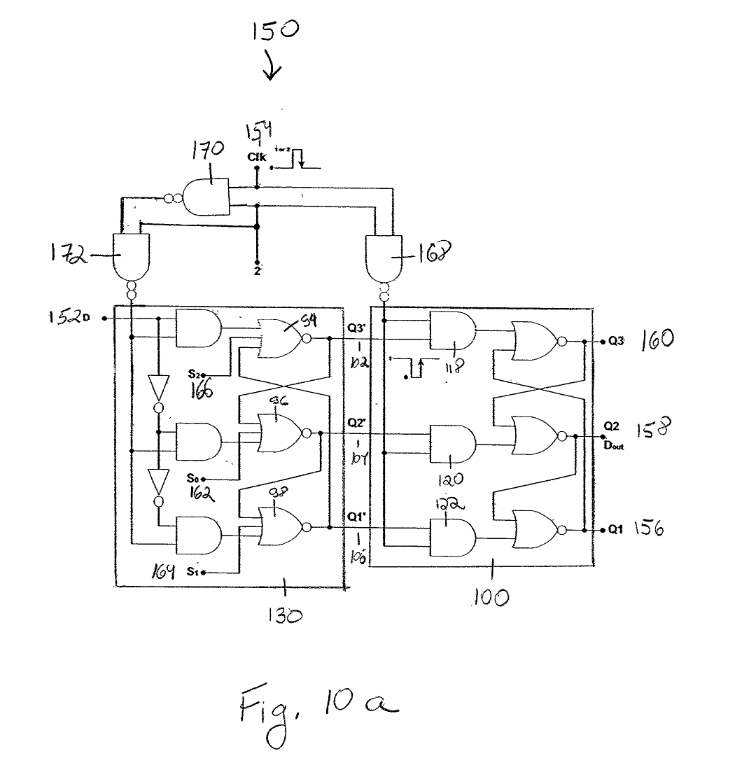

Reference is now made to FIG. 9, which is a simplified illustration of a three-state D flip-flop. The D flip-flop 130, is similar to the clocked SR flip shown in FIG. 8, with the addition of two NOT gates 132 and 134. Parts that are identical to those shown in FIGS. 7 and 8 are given the same reference numerals and are not referred to again except as necessary for an understanding of the present embodiment. D flip-flop 130 has one logic input 136. Input 136 is inverted a first time by NOT 132, and serves as an input to AND 120. Input 136 is inverted a second time by NOT 134 and serves as an input to AND 122. The second input to each of AND gates 118, 120, and 122 is a clock signal. In this embodiment the clock signal is a square wave varying between the 0 and 1 logic levels. Output Q 138 is the Q1 output of SR flip-flop 80. The Q2 and Q3 outputs of SR flip-flop 80 are not in use.

The device embodied in FIG. 9 latches the input D 136 when the clock falls to 0. While the clock is at logic level 1 output Q 138 is equivalent to the input to D 136. If D 136 changes while the clock is at logic level 1 this change is reflected directly at the output. When the clock falls to zero the current value of Q 138 is latched, and it remains unchanged until the clock signal returns to 1. The relationship between the inputs and outputs for this device is shown in Table 9.

TABLE 9
The D Flip-Flop

| Input D | Clock | Output Q |
|---|---|---|
| 0 | Trigger | 0 |
| 1 | Trigger | 1 |
| 2 | Trigger | 1 |
| Any value | 0 | No change |

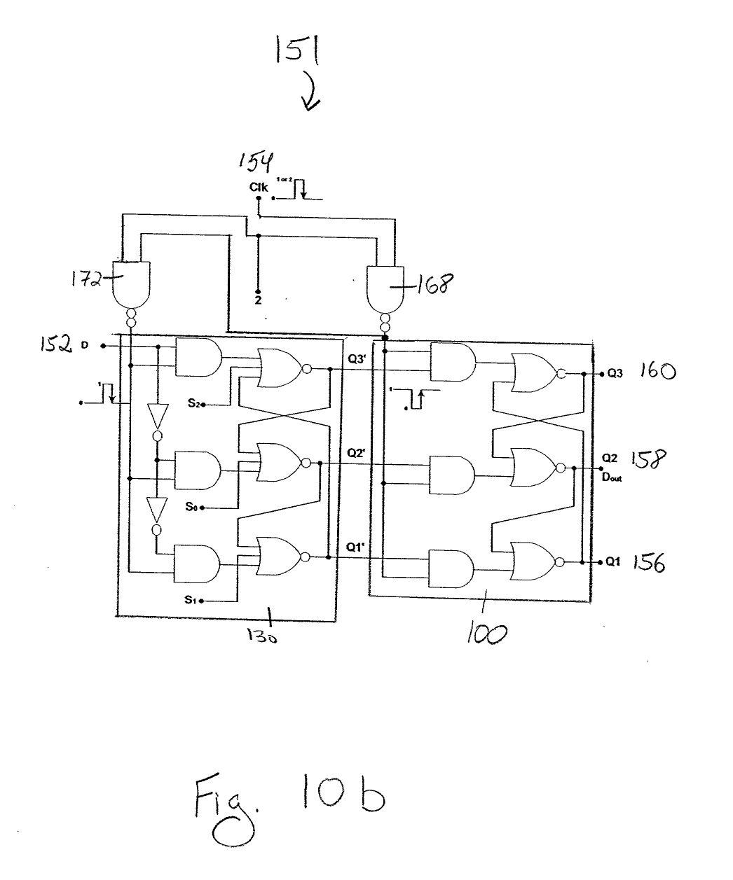

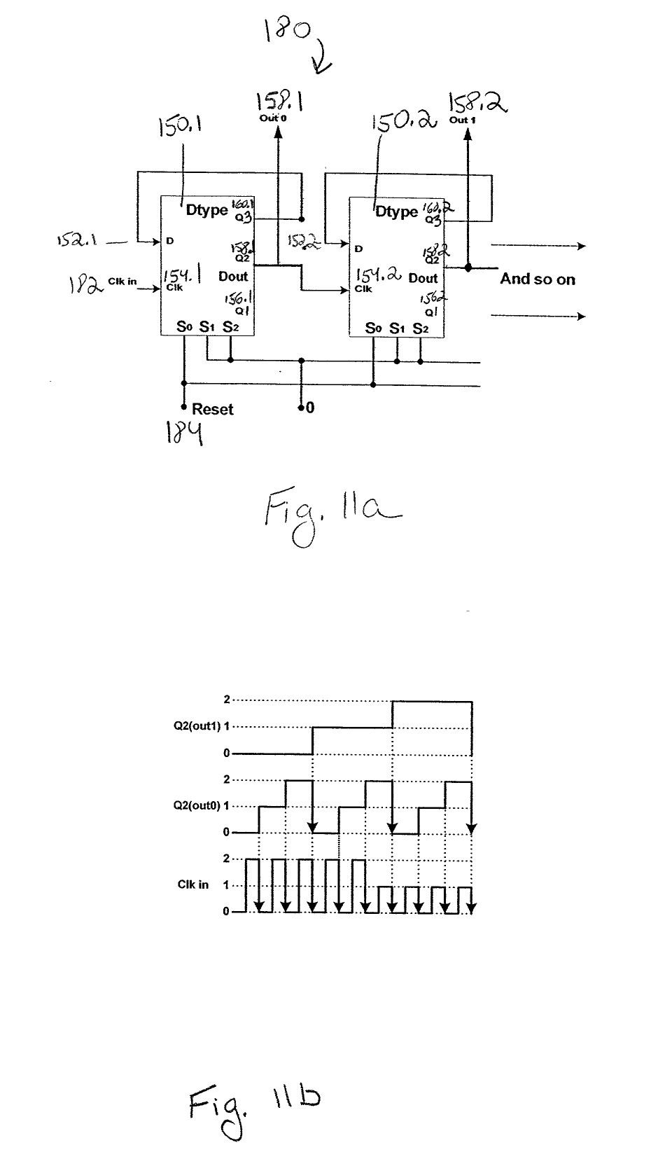

Reference is now made to FIG. 10a, which shows a simplified illustration of three-state master-slave D flip-flop. Parts that are identical to those shown in FIGS. 8 and 9 are given the same reference numerals and are not referred to again except as necessary for an understanding of the present embodiment. Master-slave D flip-flop 150, comprises one date input D 152, one clock input 154, three logic outputs Q1 156, Q2 158, and Q3 160, and three set inputs S₀ 162, S₁ 164, and S₂ 166. It comprises one modified version of the D flip-flop according to the embodiment of FIG. 9 130, one clocked SR flip-flop according to the embodiment of FIG. 8 100, and three AND gates according to the embodiment of FIG. 2 with doubly-inverted outputs 168, 170, and 172.

Logic input 152 is connected to the D input of modified D flip-flop 130. Modified D flip-flop 130 differs from a D flip-flop according to the embodiment of FIG. 9 in two ways. Firstly, NOR gates 94, 96, and 98 are three-input NORs. Each NOR gate has an additional input used as a set input, in addition to the usual inputs. Set input S₀ 162 is connected to NOR 96. Set input S₁ 164 is connected to NOR 98. Set input S₂ is connected to NOR 94. Secondly, flip-flop 130 has three outputs, which are connected to the inputs of SR flip-flop 100. These three outputs are the outputs of NOR gates 94, 96, and 98, which are connected respectively to inputs 102, 104, and 106 of SR flip-flop 100. The outputs of SR flip-flop 100 serve as the outputs 156, 158, and 160 of the master-slave D flip-flop 150.

In the embodiment of FIG. 10a the clock signal 154 is a square wave which alternates between the 0 and 1 logic levels, or between the 0 and 2 logic levels. AND gate 170 has two inputs, one of which is hard-wired to logic level (state) 2, and the other of which is connected to the clock. AND gate 172 has two inputs, one of which is hard-wired to logic level (state) 2, and the other of which is connected to the output of AND 170. AND gate 168 has two inputs, one of which is hard-wired to logic level (state) 2, and the other of which is connected to the clock. The output of AND 172 provides a clock signal for D flip-flop 130. The clock for D flip-flop 130 is 0 when the input clock 154 is 0, and 1 when the input clock is 1 or 2. The output of AND 168 provides a clock signal for SR flip-flop 100. The output of AND 168 is inverted relative to the output of AND 172, so that when the clock input to SR flip-flop 100 is at logic level 1 the clock to D flip-flop 130 is at logic level 0, and when the clock input to SR flip-flop 100 is at logic level 0 the clock to D flip-flop 130 is at logic level 1.

Reference is now made to FIG. 10b, which is a simplified diagram showing an alternate embodiment of the master-slave D flip-flop. The D flip-flop 151 of the present embodiment differs from that of FIG. 10a in that AND gate 170 is eliminated, by connecting the output of AND 168 to the input of AND 172. The clock signals to flip-flops 130 and 100 are the same as those described in the previous embodiment.

The purpose of the master-slave D flip-flop is to ensure that the device output changes no more than once during the clock cycle. In the D flip-flop 130 embodied in FIG. 9, while the clock is not at logic level 0 the device output reflects any changes at the data input. In the present embodiment of the master-slave flip flop, the slave SR flip-flop 100 receives a clock signal which is the inverse of the clock that drives master D flip-flop 130. When the clock signal 154 is not at logic level 0, the outputs of the master flip-flop 130 reflect changes at the data input D 152, but these changes are not reflected at the slave flip-flop 100 outputs since it is receiving a 0 clock signal. When the clock signal 154 goes low, the master flip-flop outputs are latched and unchanging. The slave flip-flop 100 now has a high clock signal from the output of AND gate 168, and thus the steady signals at inputs 102, 104, and 106 are output at Q1 156, Q2 158, and Q3 160, regardless of any changes to the input D 152. The relationship between the input and output signals is given in Table 10.

TABLE 10
The Master-Slave D Flip-Flop

| Input | Clock | Out₁ | Out₂ | Out₃ |
|---|---|---|---|---|
| 0 | Trigger | 2 | 0 | 1 |
| 1 | Trigger | 0 | 1 | 2 |
| 2 | Trigger | 1 | 2 | 0 |
| Any value | 0 | Unchanged | Unchanged | Unchanged |

In master-slave D flip-flops 150 and 151, the current value of the outputs can be set to one of the steady states (0,1,2), (1,2,0) or (2,0,1) by applying signals at S₀ 162, S₁ 164, and S₂ 166 while the clock is at 0. Table 11 displays the set values for this embodiment.

TABLE 11
The Set Table

| Clock | S₀ | S₁ | S₂ | Out₁ | Out₂ | Out₃ |
|---|---|---|---|---|---|---|
| 0 | 2 | 0 | 0 | 2 | 0 | 1 |
| 0 | 0 | 2 | 0 | 0 | 1 | 2 |
| 0 | 0 | 0 | 2 | 1 | 2 | 0 |

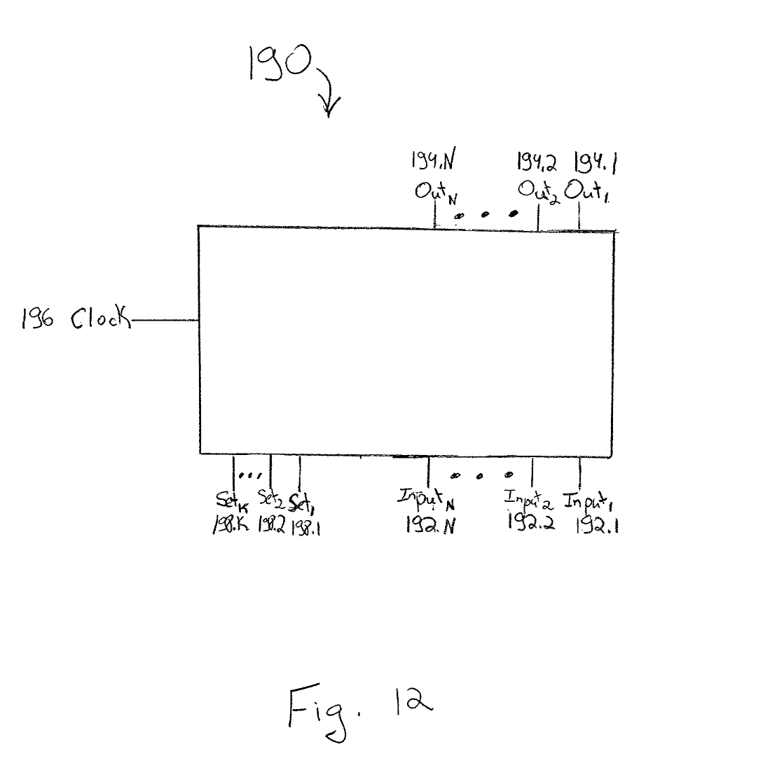

Reference is now made to FIG. 11a, which shows a simplified embodiment of a three-state asynchronous counter. Parts that are identical to those shown in FIG. 10a are given the same reference numerals and are not referred to again except as necessary for an understanding of the present embodiment. In this embodiment, an asynchronous counter 180 comprises n master-slave D flip-flops 150 chained together, where in this example n=2. The asynchronous counter is comprised of master-slave D flip-flops 150.1 and 150.2, and has one clock input 182, and one reset input 184. The Q3 output of each flip-flop 160 is fed back to its D input 152. Each flip-flop 150 in the chain provides one output 158, such that 158.1 is the least significant digit of the output and 158.n is the most significant digit.

The counter is driven by input clock 182. Each flip-flop output 158 steps from 0 to 1 to 2 on of its clock signal 154 to logic level 0. A flip-flop's Q2 output 158 serves as the clock input 154 for the subsequent flip-flop in the chain. Thus the clock signal for a given flip-flop returns to 0 only after three clock cycles of the previous flip-flop. This causes each flip-flop to count up at a third of the rate of the previous flip-flop, thereby providing the next higher significant digit. The counter is reset to 0 by applying a 2 at reset input 184 while the clock input 154 is at logic level 0.

Reference is now made to FIG. 11b, which is a waveform diagram showing the clock input signal into clock 182, and the outputs of the two successive counter stages 150.1 and 150.2 of counter 180. Out0 is the signal obtained at counter output 158.1. This counter increments each time the clock input signal falls from 2 to 0 or from 1 to 0. Out1 is the signal obtained at counter output 158.2. This counter steps up each time Out0 falls from 2 to 0. Thus counter 150.2 is incremented once for every three clock cycles of counter 150.1. Each additional stage added to the counter 180 provides a further order to the counter, by incrementing at one-third the rate of the previous stage of the counter.

In another embodiment, a synchronous counter comprises n D flip-flops. In this embodiment, the clock inputs 154 of all the D flip-flops are connected to the clock signal. The D input 152 of each flip-flop stage is a logical combination of the outputs 158 of all the previous flip-flop stages. The synchronous counter generally does not suffer from propagation delays, which may degrade the performance of an asynchronous counter.

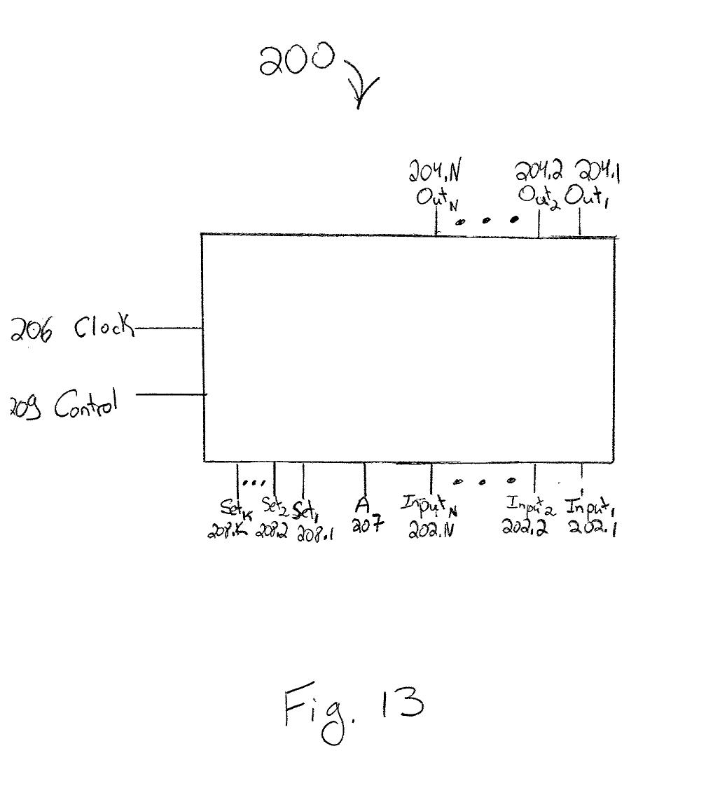

Reference is now made to FIG. 12, which is a simplified illustration of a preferred embodiment of a multi-state latch. Latch 190 comprises an N-digit input, 192.1 to 192.N an N digit output, 194.1 to 194.N, where each output digit corresponds to an input digit, a clock input 196, and K set inputs 198.1 to 198.K. In the preferred embodiment K equals the number of logic states in the logic system the latch is designed for.

In a preferred embodiment of a multi-state latch, the device is latched whenever the clock 196 undergoes a transition from a first predetermined state to a second predetermined state. When this transition occurs, the values of the outputs 194 are latched to the values of the inputs 192 at the time immediately prior to the transition. The outputs 194 remain unchanged until the next time the clock 196 undergoes the transition from the first state to the second state, or until the outputs 194 are set by applying a predetermined signal to the set inputs 198, as described below. In this embodiment, a single clock signal can be used to drive several different devices, where each device is triggered by a transition between different predefined states.

In this embodiment, the current value of the outputs 194 can be set to a particular logic level by applying a predetermined signal to the set inputs 198. Each set input 198 corresponds to a particular logic level. Applying the predetermined signal to one of the set inputs 198 causes all the output digits 194 to be set to the corresponding logic level. In another embodiment, the outputs 194 can be set only during a predetermined portion of the clock signal 196.

In another embodiment of a multi-state latch, the latch additionally has a transparent mode. The latch enters this mode whenever the clock input 196 is at a predetermined level. When the latch is in transparent mode, the logic level present at each input 192 is reflected directly at the corresponding output 194.

In another embodiment of a multi-state latch, the clock signal 196 is a square wave that alternates between a first and a second logic level, so that a complete clock cycle comprises two transitions of the clock signal 196. During the interval between the first and second transitions, the latch is transparent and the logic level present at each input 192 is reflected directly at the corresponding output 194. During the interval between the second and first transitions, the values of the outputs 194 are latched, and they remain unchanged until the clock signal 196 undergoes another transition.

A preferred embodiment of a three-state latch comprises an N-digit input, 192.1 to 192.N, an N digit output, 194.1 to 194.N, a clock input 196, and 3 set inputs 198.1 (Set₁), 198.2 (Set₂) and 198.3 (Set₃). The clock signal 196 alternates between logic state A, where A may be any of the three logic states, and logic state B, where B is one of the two logic states that are not equal to state A. Thus during the interval between the first transition and the second transition the clock 196 is at state A, and during the interval between the second transition and the first transition the clock 196 is at a state other than state A. The relationship between the input 192 and output 194 is given in the following table.

| Inputᵢ | | Outputᵢ |
|---|---|---|
| 1 < i < N | Clock | 1 < i < N |
| 0 | A | 0 |
| 1 | A | 1 |
| 2 | A | 2 |
| Any value | A value other than A | Inputᵢ prior to the |
| | | transition |

In this embodiment the outputs 194 can be set at any time in the clock cycle, by applying the appropriate signals to the set inputs 198. The outputs 194 are set when a 1 is applied to any of the set inputs 198. The following table displays the set values for this embodiment.

| Inputᵢ | | | | | Outputᵢ |
|---|---|---|---|---|---|
| 1 < i < N | Clock | Set₁ | Set₂ | Set₃ | 1 < i < N |
| Any value | Any value | 1 | 0 | 0 | 0 |
| Any value | Any value | 0 | 1 | 0 | 1 |
| Any value | Any value | 0 | 0 | 1 | 2 |

In other embodiments the latch set table may be substantially different. In one embodiment, the latch outputs 194 are settable only during a certain portion of the clock cycle.

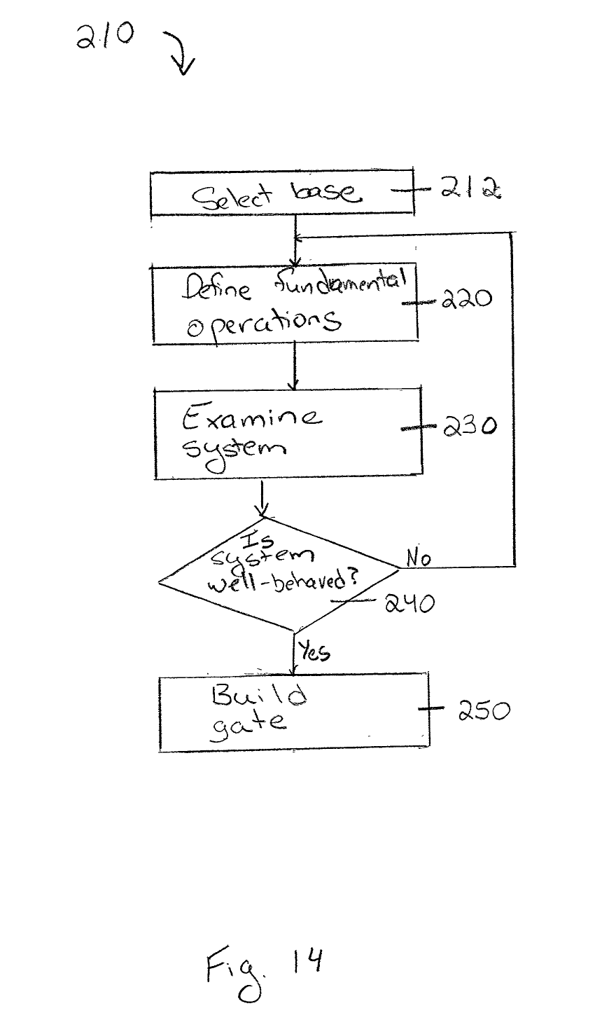

Reference is now made to FIG. 13, which is a simplified illustration of a preferred embodiment of a multi-state shift-register. Shift register 200 comprises an N-digit input, 202.1 to 202.N, an N digit output, 204.1 to 204.N, where each output digit corresponds to an input digit, a clock input 206, a data input A 207, and K set inputs 208.1 to 208.K, and a control input 209. In the preferred embodiment K equals the number of logic states in the logic system the shift register is designed for. Shift register 200 operation is similar to a latch, with the addition of the capability of shifting the outputs left or right in response to the control input.

The control input 209 determines the shift register mode of operation. In the current embodiment the shift register functions as a latch when control input 209 is 0, shifts left when control input 209 is 1, and shifts right when control input 209 is 2. When shift register 200 functions as a latch its operation is equivalent to the embodiment of a multi-state latch described above.

When shift register 200 shifts left the values of the outputs are shifted one digit to the left after the second transition, so that the value of output Out₁ 204.i is changed to the value of Outᵢ₋₁ 204.i+1 before the transition. In this embodiment, the value of output Out_{N} 204.1 after the transition is the level at input A 207 immediately prior to the transition. These output values do not change until the next clock transition from the first to the second predetermined state.

When shift register 200 shifts right the values of the outputs are shifted one digit to the right after the second transition, so that the value of output Outᵢ 204.i is changed to the value of Outᵢ₊₁ 204.i+1 before the transition. In this embodiment, the value of output Out_{N} 204.N after the transition is the level at input A 207 immediately prior to the transition. These output values do not change until the next clock transition from the first to the second predetermined state.

In another embodiment the value of Out₁ 204.1 after left shift, and the value of Out_{N} 204.N after right shift are a predetermined logic level. In an additional embodiment, the extreme value that is shifted out of the shift register 200 is fed back to the other end of the register. In this embodiment the value of Out₁ 204.1 after left shift is the value of Out_{N} 204.N before the shift, and the value of Out_{N} 204.N after right shift is the value of Out₁ 204.1 before the shift.

In shift register 200, the set inputs 208 function in the same manner as the set inputs in the multi-state latch. In this embodiment the outputs 204 are set to a particular logic level by applying a predetermined signal to the set inputs 208. Each set digit corresponds to a particular logic level. Applying the predetermined signal to one of the set digits causes all the output digits 204 to be set to the corresponding logic level. In another embodiment, the outputs can be set only during a predetermined portion of the clock signal.

A second preferred embodiment of a three-level logic system makes use of logical operations as defined below.

The truth table for a NOT operation according to the second embodiment is given in Table 7.

TABLE 7
The NOT Operation

| A | A# |
|---|---|
| 0 | 2 |
| 1 | 0 |
| 2 | 1 |

It is seen from Table 7 that the NOT operation is cyclic, in that given a cyclic input the NOT gate produces a cyclic output. An input of (0,1,2) produces an output of (2,0,1). Two NOT gates in succession, X##, produce a cyclic output in the reverse direction. That is, an input of (0,1,2) produces an output of (1,2,0).

The truth table for an AND operation according to the second embodiment is given in Table 8.

TABLE 8
The AND Operation

| A | B | A*B |
|---|---|---|
| 0 | 0 | 0 |
| 0 | 1 | 0 |
| 0 | 2 | 0 |
| 1 | 0 | 0 |
| 1 | 1 | 1 |
| 1 | 2 | 1 |
| 2 | 0 | 0 |
| 2 | 1 | 1 |
| 2 | 2 | 2 |

The truth table for an OR operation according to the second embodiment is given in Table 9.

| A | B | A + B |
|---|---|---|
| 0 | 0 | 0 |
| 0 | 1 | 1 |
| 0 | 2 | 2 |
| 1 | 0 | 1 |
| 1 | 1 | 1 |
| 1 | 2 | 1 |

TABLE 3
The OR Operation

| A | B | A + B |
|---|---|---|
| 2 | 0 | 2 |
| 2 | 1 | 1 |
| 2 | 2 | 2 |

This base-3 logic system obeys the following mathematical rules:

| Rule No. | Rule | Rule Name |
|---|---|---|
| 1. | X## = (X#)# | |
| 2. | X### = X | Triple Complement Law |
| 3. | X + Y = Y + X | Commutative Law |
| | X * Y = Y * X | |
| 4. | (X + Y) +Z = X + (Y + Z) | Associative Law |
| | (X * Y) * Z = X * (Y * Z) | |
| 5. | X + 0 = X | Identity Laws |
| | X * 2 = X | |
| 6. | X + 1 = 1 | Dominance Laws |
| | X * 0 = 0 | |
| 7. | X + X = X | Idempotent Laws |
| | X * X = X | |
| 8. | X + X# + X## = 1 | Complement Laws |
| | X * X# * X## = 0 | |
| 9. | X * (Y + Z) = X * Y + X * Z | Distributive Law |
| 10. | X * Y + X = X * (Y + 2) | |

| Rule No. | Rule | Rule Name |
|---|---|---|
| 11. | X## + Y## + Z##. . . = (X * Y * Z * . . .)## | Demorgan's |
| | | Laws |
| | X# * Y# * Z#. . . = (X + Y + Z +. . .)# | |
| 12. | X + (Y#) = X + Y# | |
| | X * (Y#) = X * Y# | |
| 13. | X + ((Y#)#) = X + Y## | |
| | X * ((Y#)#) = X * Y## | |
| 14. | (X#) + Y = X# + Y | |
| | (X#) * Y = X# * Y | |
| 15. | ((X#)#) + Y = X## + Y | |
| | ((X#)#) * Y = X## * Y | |
| 16. | (X + Y) + Z = X + Y + Z | |

The equations in this table are useful for minimizing equations in the logic system according to the second preferred embodiment, by eliminating variables from the equation.

The operation of “Identifying the Variable” is defined for the logic system according to the second preferred embodiment. The preferred embodiment of the “Identifying the Variable” operation isolates a variable, so that the logic output is set to a predetermined value if the input is the desired logic level. The identification operation is defined by the following truth table:

TABLE 4
The Identifying the Variable Operation

| A | id01(A) | id02(A) | id11(A) | id12(A) | id21(A) | id22(A) |
|---|---|---|---|---|---|---|
| 0 | 1 | 2 | 0 | 0 | 0 | 0 |
| 1 | 0 | 0 | 1 | 2 | 0 | 0 |
| 2 | 0 | 0 | 0 | 0 | 1 | 2 |

The mathematical relationship for these operations is shown below:

id01(A)=(A#)*(A##)

id02(A)=(1*A)#

id11(A)=A*(A##)

id12(A)=(1*A#)#

id21(A)=A*(A#)

id22(A)=(1*A##)#

Logic devices implementing an arbitrary truth table can be developed in accordance with these definitions, as they were for the first system.

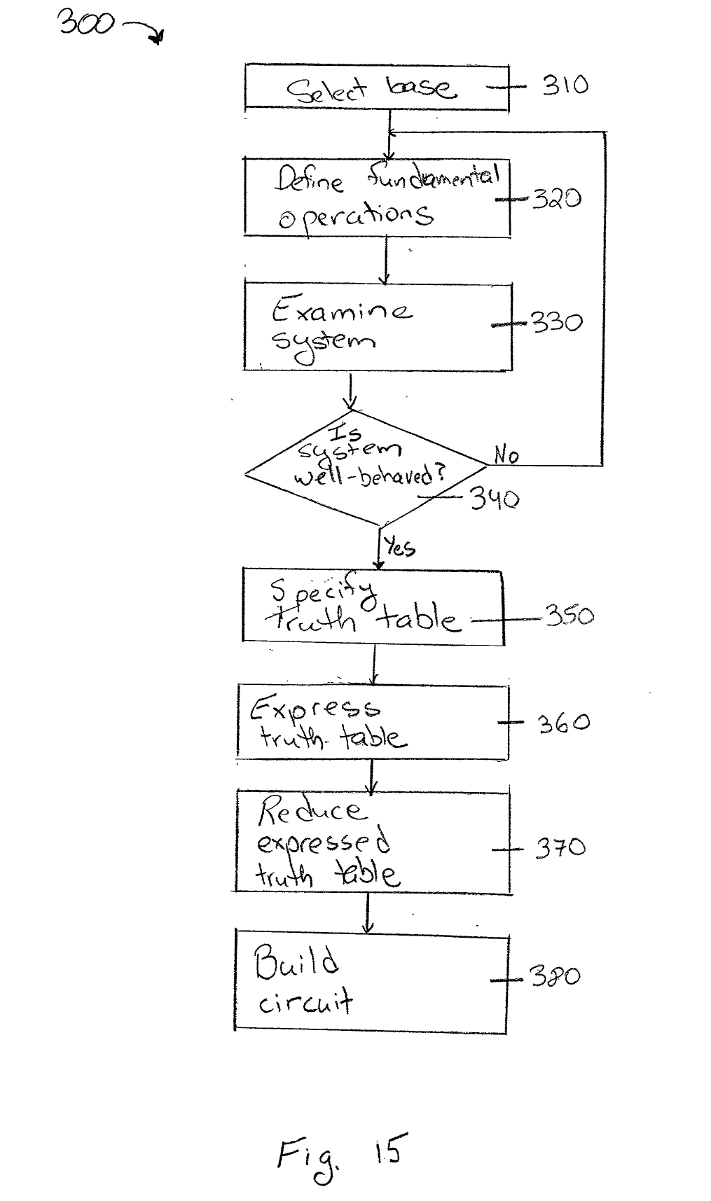

Reference is now made to FIG. 14, which is a block diagram of an embodiment of a simplified method for designing a non-binary digital logic system and building logic gates that conform to this system 210. A base for non-binary digital operations is selected 212. This base is an integer greater than two, which specifies the number of states a variable may assume. For example, selecting a base of three results in a trinary logic device. Next the fundamental operations, AND, OR, and NOT, are defined to form a particular embodiment of a logic system 220. The definitions of the fundamental operations determine the higher level behavior of the system. In order to obtain a logic system with useful behavior, the NOT operation should be defined to be cyclic. The system behavior is examined 230 to determine if it possesses a zero member, a one member, and obeys the laws of Idempotent, Complement, Dominance, and Commutation. In this embodiment these laws are expressed by the following identities:

X+X=X

X*X=X

X+X#+X##=2

X*X#*##=0

X+2=2

X*0=0

X+Y=Y+X

X*Y=Y*X

X+0=X

X*1=X

If the NOT operation is cyclic and the system obeys the identities listed above, the system is considered well behaved and the design procedure continues. If the system does not obey the above identities, the fundamental operations, AND, OR, and NOT, are redefined until a well-behaved system is obtained 240. Once a well-behaved system is established logic gates can be built according to the definitions of the fundamental logic operation 250.

In another embodiment, a well-behaved system is required to obey the distributive and associative laws, in addition to the laws listed above. The distributive law is defined by the following identity:

X*(Y+Z)=X*Y+X*Z

The associative law is defined by the following identities:

(X+Y)+Z=X+(Y+Z)

(X*Y)*Z=X*(Y*Z)

In this embodiment, these laws are added to the list of identities that the system is required to obey in order to be considered well behaved.

In an additional embodiment, defining the fundamental operations so that the system conforms to DeMorgan's Laws may result in a system that is easily simplified, thereby yielding less complex circuit designs. In this embodiment, these laws are:

X#+Y#+Z# . . . =(X*Y*Z . . . )#

X##*Y##+Z## . . . =(X+Y+Z . . . )##

In this embodiment, these laws are added to the list of identities that are used to determine if the defined system is well behaved.

In another embodiment, DeMorgan's Laws are given an alternate formulation. In this formulation the laws are expressed as follows:

Where:

1. n, N, K, R, T, M are natural numbers.

2. n>=2

3. N is the number of states of the logical system.

4. 1<=K<=N

5. 1<=R<=N

6. 1<=T<=N

7. 1<=M<=N

This embodiment is appropriate for logic systems with an arbitrary base, where N equals the base of the logic system.

Reference is now made to FIG. 15, which is a block diagram of an embodiment of a simplified method for designing and building non-binary digital logic devices that conform to an arbitrary truth table 300. A base is selected for the system 310, and the fundamental logic operations, AND, OR, and NOT, are defined 320. The system's high-level behavior examined 330, and the fundamental operations redefined until a well-behaved system is established 340. Once a well-behaved system has been defined, an arbitrary truth table is specified 350. The fundamental operations are then used to express the truth table outputs as functions of the inputs 360. If functions substantially like an “Identifying the Variable” operation are defined, the truth table may be expressed by a method similar to a sum of the products representation. If possible, these expressions may be reduced using the listed identities to yield simplified expressions 370. Finally, a digital circuit is built by connecting logic gates according to the simplified expressions 380. This digital circuit conforms to the given truth table, in that for each combination of input signals the circuit output equals the output stated in the truth table.

The devices embodied in FIGS. 4 to 15 demonstrate that it is feasible to develop 3-level logic devices. These logic devices form a basis for development of other computer components, such as shift registers, and JK flip-flops. These devices can be used to develop computer software and hardware based upon the base-3 logic system described in this embodiment.

Embodiments of logical systems for more than three symbols can provide even greater simplification of computer design. The methods of FIGS. 14 and 15 provide useful systems that conform to fundamental mathematical laws such as commutation and identity, and for which effective circuit design is possible. Several embodiments of a logic system may be possible for any given system base. The possible embodiments should be examined to identify systems that provide maximal circuit design benefits.

Embodiments of non-binary logic systems provide a method for simplifying computer and digital logic circuit complexity. Developing technologies, such as optical computing and molecular computing, are promising avenues for implementation of base-3 logic in the computing environment. A computer using base-3 logic may require fewer data bus wires than a binary computer. The number of wires may be reduced approximately by a factor of (⅔)^{N}, where N is the number of data bus or address bus wires for an equivalent binary computer. The use of base-3 logic for integrated circuit (IC) design may reduce the number of pins required, a factor that is becoming a concern in integrated circuit design today. Additionally, a base-3 computer may require fewer transistors and gates. Base-3 computers may thus be smaller, faster, and cheaper than their binary counterparts.

It is appreciated that certain features of the invention, which are, for clarity, described in the context of separate embodiments, may also be provided in combination in a single embodiment. Conversely, various features of the invention which are, for brevity, described in the context of a single embodiment, may also be provided separately or in any suitable sub-combination.

It will be appreciated by persons skilled in the art that the present invention is not limited to what has been particularly shown and described hereinabove. Rather the scope of the present invention is defined by the appended claims and includes both combinations and subcombinations of the various features described hereinabove as well as variations and modifications thereof which would occur to persons skilled in the art upon reading the foregoing description.

We claim:

1. A digital logic element comprising at least one input and at least one output, each input and each output being capable of assuming a number of logic states, and a logical operation relating said logic states at said input with logic states at said output, and wherein said number of logic states is at least three.

2. A digital logic element according to claim 1, wherein said number of logic states is three, comprising a first state (0), a second state (1), and a third state (2).

3. A digital logic element according to claim 1, wherein said logic states comprise a predetermined set of values of the following types of signals: voltage, current, impedance, nuclear spin, quantum state, polarity, and phase.

4. A digital logic element according to claim 2, for carrying out a first logical operation, the element having one input (A) and one output (B), and wherein said first logical operation is substantially defined by the following table:

| Input A | Output B |
|---|---|
| 0 | 2 |
| 1 | 0 |
| 2 | 1 |

5. A digital logic element according to claim 4, being insertable into circuitry for use as a NOT gate.

6. A digital logic element according to claim 2, for carrying out a second logical operation, the element having a first input (A), a second input (B) and an output (C), and wherein said second logical operation is substantially defined by the following table:

| Input A | Input B | Output C |
|---|---|---|
| 0 | 0 | 0 |
| 0 | 1 | 0 |
| 0 | 2 | 0 |
| 1 | 0 | 0 |
| 1 | 1 | 1 |
| 1 | 2 | 2 |
| 2 | 0 | 0 |
| 2 | 1 | 2 |
| 2 | 2 | 2 |

7. A digital logic gate according to claim 6, being insertable into circuitry for use as an AND gate.

8. A digital logic element according to claim 2, for carrying out a third logical operation, the element having a first input (A), a second input (B) and an output (C), and wherein said third logical operation is substantially defined by the following table:

| Input A | Input B | Output C |
|---|---|---|
| 0 | 0 | 0 |
| 0 | 1 | 1 |
| 0 | 2 | 2 |
| 1 | 0 | 1 |
| 1 | 1 | 1 |
| 1 | 2 | 2 |
| 2 | 0 | 2 |
| 2 | 1 | 2 |
| 2 | 2 | 2 |

9. A digital logic element according to claim 8, being insertable into circuitry for use as an OR gate.

10. A digital logic element according to claim 2, for carrying out a fourth logical operation, the element having a first input (A), a second input (B) and an output (C), and wherein said fourth logical operation is substantially defined by the following table:

| Input A | Input B | Output C |
|---|---|---|
| 0 | 0 | 0 |
| 0 | 1 | 0 |
| 0 | 2 | 0 |
| 1 | 0 | 0 |
| 1 | 1 | 1 |
| Input A | Input B | Output C |
|---|---|---|
| 1 | 2 | 1 |
| 2 | 0 | 0 |
| 2 | 1 | 1 |
| 2 | 2 | 2 |

11. A digital logic element according to claim 10, being insertable into circuitry for use as an AND gate.

12. A digital logic element according to claim 2, for carrying out a fifth logical operation, the element having a first input (A), a second input (B) and an output (C), and wherein said fifth logical operation is substantially defined by the following table:

| Input A | Input B | Output C |
|---|---|---|
| 0 | 0 | 0 |
| 0 | 1 | 1 |
| 0 | 2 | 2 |
| 1 | 0 | 1 |
| 1 | 1 | 1 |
| 1 | 2 | 1 |
| 2 | 0 | 2 |
| 2 | 1 | 1 |
| 2 | 2 | 2 |

13. A digital logic element according to claim 12, being insertable into circuitry for use as an OR gate.

14. A digital logic element according to claim 2, comprising a programmable logic array operable to implement a truth table involving said three logic states.

15. A digital logic element according to claim 2, for carrying out a sixth logical operation, being insertable into circuitry for use as a full adder.

16. A digital logic element according to claim 15, the element having a first input (A), a second input (B), a third input (Carryᵢₙ), a first output (Sum), and a second output (Carryₒᵤₜ), and wherein said logical operation is substantially defined by the following table:

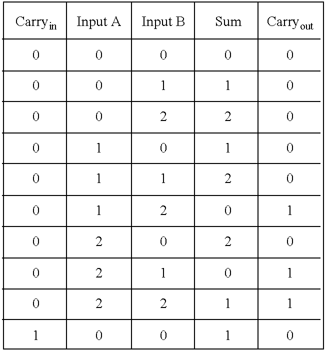

| Carryᵢₙ | Input A | Input B | Sum | Carryₒᵤₜ |
|---|---|---|---|---|
| 1 | 0 | 1 | 2 | 0 |
| 1 | 0 | 2 | 0 | 1 |
| 1 | 1 | 0 | 2 | 0 |
| 1 | 1 | 1 | 0 | 1 |
| 1 | 1 | 2 | 1 | 1 |
| 1 | 2 | 0 | 0 | 1 |
| 1 | 2 | 1 | 1 | 1 |
| 1 | 2 | 2 | 2 | 1 |
| 2 | 0 | 0 | 2 | 0 |
| 2 | 0 | 1 | 0 | 1 |
| 2 | 0 | 2 | 1 | 1 |
| 2 | 1 | 0 | 0 | 1 |
| 2 | 1 | 1 | 1 | 1 |
| 2 | 1 | 2 | 2 | 1 |
| 2 | 2 | 0 | 1 | 1 |
| 2 | 2 | 1 | 2 | 1 |
| 2 | 2 | 2 | 0 | 2 |

17. A digital logic element according to claim 2, for carrying out a seventh logical operation, being insertable into circuitry for use as a NOR gate.

18. A digital logic element according to claim 17, the element having a first input (A), a second input (B) and an output (C), and wherein said logical operation is substantially defined by the following table:

| Input A | Input B | Output C |
|---|---|---|
| 0 | 0 | 2 |
| 0 | 1 | 0 |
| 0 | 2 | 1 |
| 1 | 0 | 0 |
| 1 | 1 | 0 |
| 1 | 2 | 1 |
| 2 | 0 | 1 |
| 2 | 1 | 1 |
| 2 | 2 | 1 |

19. A digital logic element according to claim 2, for carrying out an eighth logical operation, being insertable into circuitry for use as an SR flip-flop.

20. A digital logic element according to claim 19, the element having a first input (A), a second input (B), a third input (C), a first output (D), a second output (E), and a third output (F), and wherein said logical operation is substantially defined by the following table:

| | | | Previous | Next |
|---|---|---|---|---|
| | | | Outputs | Outputs |
| Input A | Input B | Input C | (D, E, F) | (D, E, F) |
| 0 | 0 | 0 | (0, 1, 2) | (0, 1, 2) |
| 0 | 0 | 0 | (1, 2, 0) | (1, 2, 0) |
| 0 | 0 | 0 | (2, 0, 1) | (2, 0, 1) |
| 0 | 0 | 1 | (0, 1, 2) | (0, 1, 2) |
| | | | Previous | Next |
|---|---|---|---|---|
| | | | Outputs | Outputs |
| Input A | Input B | Input C | (D, E, F) | (D, E, F) |
| 0 | 0 | 1 | (1, 2, 0) | (1, 2, 0) |
| 0 | 0 | 1 | (2, 0, 1) | (0, 1, 2) |
| 0 | 0 | 2 | (1, 2, 0) | |
| 0 | 1 | 0 | (0, 1, 2) | (0, 1, 2) |
| 0 | 1 | 0 | (1, 2, 0) | (2, 0, 1) |
| 0 | 1 | 0 | (2, 0, 1) | (2, 0, 1) |
| 0 | 1 | 1 | (0, 1, 2) | |
| 0 | 1 | 2 | (1, 0, 0) | |
| 0 | 2 | 0 | (0, 1, 2) | |
| 0 | 2 | 1 | (0, 1, 2) | |
| 0 | 2 | 2 | (1, 1, 0) | |
| 1 | 0 | 0 | (0, 1, 2) | (1, 2, 0) |
| 1 | 0 | 0 | (1, 2, 0) | (1, 2, 0) |
| 1 | 0 | 0 | (2, 0, 1) | (2, 0, 1) |
| 1 | 0 | 1 | (1, 2, 0) | |
| 1 | 0 | 2 | (1, 2, 0) | |
| 1 | 1 | 0 | (2, 0, 1) | |
| 1 | 1 | 1 | (0, 0, 0) | |
| 1 | 1 | 2 | (1, 0, 0) | |
| 1 | 2 | 0 | (0, 1, 0) | |
| 1 | 2 | 1 | (0, 1, 0) | |
| 1 | 2 | 2 | (1, 1, 0) | |
| | | | Previous | Next |
|---|---|---|---|---|
| | | | Outputs | Outputs |
| Input A | Input B | Input C | (D, E, F) | (D, E, F) |
| 2 | 0 | 0 | | (2, 0, 1) |
| 2 | 0 | 1 | | (0, 0, 1) |
| 2 | 0 | 2 | | (1, 0, 1) |
| 2 | 1 | 0 | | (2, 0, 1) |
| 2 | 1 | 1 | | (0, 0, 1) |
| 2 | 1 | 2 | | (1, 0, 1) |
| 2 | 2 | 0 | | (0, 1, 1) |
| 2 | 2 | 1 | | (0, 1, 1) |
| 2 | 2 | 2 | | (1, 1, 1) |

21. A digital logic element according to claim 2, for carrying out a ninth logical being insertable into circuitry for use as a D flip-flop.

22. A digital logic element according to claim 21, the element having a first input (A), a second input (Clock), and one output (Out₁), and wherein said logical operation is substantially defined by the following table:

| Input A | Clock | Out₁ |
|---|---|---|
| 0 | Trigger | 0 |
| 1 | Trigger | 1 |
| 2 | Trigger | 2 |
| Any value | 0 | Unchanged |

23. A digital logic element according to claim 2, for carrying out a tenth logical operation, being insertable into circuitry for use as a master-slave D flip-flop.

24. A digital logic element according to claim 23, the element having a first input (A), a second input (Clock), a third input (Set₀), a fourth input (Set₁), a fifth input (Set₂), a first output (Out₁), a second output (Out₂), and a third output (Out₃), wherein said second input repetitively undergoes a cycle comprising a first and a second transition, and wherein said logical operation is substantially defined by the following table:

| Input A | Clock | Out₁ | Out₂ | Out₃ |
|---|---|---|---|---|
| 0 | First | 2 | 0 | 1 |
| | transition | | | |
| 1 | First | 0 | 1 | 2 |
| | transition | | | |
| 2 | First | 1 | 2 | 0 |
| | transition | | | |
| Any value | 0 | Unchanged | Unchanged | Unchanged |

and wherein the value of the outputs can be set while the clock is at 0 by applying signals at Set₀, Set₁, and Set₂, substantially according to the following table:

| Input A | Clock | Set₀ | Set₁ | Set₂ | Out₁ | Out₂ | Out₃ |
|---|---|---|---|---|---|---|---|
| Any value | 0 | 2 | 0 | 0 | 2 | 0 | 1 |
| Any value | 0 | 0 | 2 | 0 | 0 | 1 | 2 |
| Any value | 0 | 0 | 0 | 2 | 1 | 2 | 0 |

25. A digital logic element according to claim 2, for carrying out an eleventh logical operation, being insertable into circuitry for use as a master-slave D flip-flop element.

26. A digital logic element according to claim 25, the element having a first input (A), a second input (Clock), and at least one output (Out₁), wherein the output is changeable only by a predetermined trigger applied to the clock input, said trigger being operable to set the output to the value of said input immediately prior to said trigger.

27. A digital logic element according to claim 2, for carrying out a twelfth logical operation, being insertable into circuitry for use as a D flip-flop.

28. A digital logic element according to claim 27, the element having a first input (A), a second input (Clock), and one output (Out₁), wherein while said second input is at a predetermined logic state said output is operable to be equal to said first input, and which output is latchable to its current state upon application of a predetermined trigger to said second input, to remain at said current state until said second input returns to said predetermined logic state.

29. A digital logic element according to claim 2, for carrying out a thirteenth logical operation, the element having one input (A) and one output (B), and wherein said logical operation is substantially defined by the following table:

| Input A | Output B |
|---|---|
| 0 | 1 |
| 1 | 2 |
| 2 | 0 |

30. A digital logic element according to claim 29, being insertable into circuitry for use as a NOT gate.

31. A digital logic element according to claim 2, for carrying out a fourteenth logical operation, being insertable into circuitry for use as an SR flip-flop.

32. A digital logic element according to claim 31, the element having a first input (A), a second input (B), a third input (C), a first output (D), a second output (E), and a third output (F), wherein if the values of said outputs are at one of a set of predetermined steady states said outputs are latchable to their current states upon application of predetermined logic states to said first, second, and third inputs, to remain at said current states until different logic states are applied to said first, second, and third inputs.

33. A digital logic element according to claim 2, for carrying out a fifteenth logical operation, being insertable into circuitry for use as a clocked SR flip-flop.

34. A digital logic element according to claim 33, having a first input (A), a second input (B), a third input (C), a fourth input (Clock), a first output (Q1), a second output (Q2), and a third output (Q3), wherein a clock signal varying between a first and a second logic state is applicable to said fourth input, and wherein if the values of said outputs are at one of a set of predetermined steady states said outputs are latchable to their current states upon application of a predetermined trigger to said fourth input, to remain at said states until different logic states are applied to said inputs.

35. A digital logic element according to claim 1, for carrying out a sixteenth logical operation, being insertable into circuitry for use as a multi-state latch.

36. A digital logic element according to claim 35, the element having a first input (Input), which input comprises N digits, Input₁ . . . Input_{N}, a second input (Clock), and an output (Out), which output comprises N digits, Out₁ . . . Out_{N}, and wherein each output digit corresponds to an input digit, wherein all of said inputs and outputs are capable of assuming one of a plurality of logic states, and wherein said second input is operable to undergo a series of transitions, wherein said outputs are changeable only by a predetermined transition of the second input, said transition being operable to set each output digit to the value of its corresponding input digit immediately prior to said transition.

37. A digital logic element according to claim 36, wherein each output digit is operable to be equal to its corresponding input digit when said second input is at a predetermined logic state.

38. A digital logic element according to claim 36, further comprising a third input (Set), which input comprises a plurality of digits, wherein each digit corresponds to a logic state, and wherein said element is operable to have said N output digits set to a particular logic state when a predetermined signal is applied to the digit of said third input corresponding to said logic state.

39. A digital logic element according to claim 38, wherein the N output digits are setable to a particular logic state when a predetermined signal is applied to said third input only when the second input is at a predetermined state.

40. A digital logic element according to claim 36, for carrying out a seventeenth logical operation, wherein the number of logic states that all inputs and all outputs may assume is three, and being insertable into circuitry for use as a three-state latch.

41. A digital logic element according to claim 40, further comprising a third input (Set₀), a fourth input (Set₁), and a fifth input (Set₂), wherein the N outputs digits are setable by applying signals to Set₀, Set₁, and Set₂, substantially according to the following table:

| Inputᵢ | Set₀ | Set₁ | Set₂ | Outᵢ |
|---|---|---|---|---|
| i = 1 to N | | | | 1 = 1 to N |
| Any value | A | A value other | A value other | 0 |
| | | than A | than A | |
| Any value | A value other | A | A value other | 1 |
| | than A | | than A | |
| Any value | A value other | A value other | A | 2 |
| | than A | than A | | |

42. A digital logic element according to claim 41, wherein the N output digits are setable to a particular logic state by applying signals at Set₀, Set₁, and Set₂, only when the second input is at a predetermined state.

43. A digital logic element according to claim 1, for carrying out an eighteenth logical operation, being insertable into circuitry for use as a multi-state shift register.

44. A digital logic element according to claim 43, operable to shift left, shift right, and latch.

45. A digital logic element according to claim 44, the element having a first input (Input), which input comprises N digits, Input₁ . . . Input_{N}, a second input (Clock), a third input (A), a fourth input (Control), and an output (Out), which output comprises N digits, Out₁ . . . Out_{N}, and wherein each output digit corresponds to an input digit, wherein said second input is operable to undergo a series of transitions, wherein said outputs are changeable by a predetermined transition of the second input, wherein if the value of said fourth input equals a first predetermined value said transition is operable shift the output left, if the value of said fourth input equals a second predetermined value said transition is operable shift the output right, and if the value of said fourth input equals a third predetermined value said transition is operable to latch the output to the value of the input immediately prior to said transition.

46. A digital logic element according to claim 45, further comprising a fifth input (Set), which input comprises a plurality of digits, wherein each digit corresponds to a logic state, and wherein said element is operable to have the N output digits set to a particular logic state when a predetermined signal is applied to the digit of said fifth input corresponding to said logic state

47. A digital logic element according to claim 46, wherein each output digit is operable to be equal to its corresponding input digit when said second input is at a predetermined logic state.

48. A digital logic element according to claim 45, wherein if the input is shifted left the value of Out₁ is operable to be set to a predetermined value, and if the input is shifted right the value of Out_{N} is operable to be set to a predetermined value.

49. A digital logic element according to claim 45, wherein if the input is shifted left the value of Out₁ is operable to be set to the value of the third input immediately prior to said transition, and if the input is shifted right the value of Out_{N} is operable to be set to the value of the third input immediately prior to said transition.

50. A digital logic circuit, comprising a plurality of digital logic elements, each having at least one input and at least one output, each input and each output being able to assume any one of a group of three logic states, comprising a first state (0), a second state (1), and third state (2), and wherein a logic operation relates said logic states at said at least one input to said logic states at said at least one output, the logic elements being any one of a group comprising:
a first digital logic element for carrying out a logical operation, the element having one input (A) and one output (B), said logical operation being substantially defined by the following table:

| Input A | Output B |
|---|---|
| 0 | 2 |
| 1 | 0 |
| 2 | 1 |

a second digital logic element for carrying out a logical operation, the element having a first input (A), a second input (B), and one output (C), said logical operation being substantially defined by the following table:

| Input A | Input B | Output C |
|---|---|---|
| 0 | 0 | 0 |
| 0 | 1 | 0 |
| 0 | 2 | 0 |
| 1 | 0 | 0 |
| 1 | 1 | 1 |
| 1 | 2 | 2 |
| 2 | 0 | 0 |
| 2 | 1 | 2 |
| 2 | 2 | 2 |

a third digital logic element for carrying out a logical operation, the element having a first input (A), a second input (B), and one output (C), said logical operation being substantially defined by the following table:

| Input A | Input B | Output C |
|---|---|---|
| 0 | 0 | 0 |
| 0 | 1 | 1 |
| 0 | 2 | 2 |
| 1 | 0 | 1 |
| 1 | 1 | 1 |
| 1 | 2 | 2 |
| 2 | 0 | 2 |
| 2 | 1 | 2 |
| 2 | 2 | 2 |

a fourth digital logic element for carrying out a logical operation, the element having a first input (A), a second input (B), and one output (C), said logical operation being substantially defined by the following table:

| Input A | Input B | Output C |
|---|---|---|
| 0 | 0 | 0 |
| 0 | 1 | 0 |
| 0 | 2 | 0 |
| 1 | 0 | 0 |
| 1 | 1 | 1 |
| 1 | 2 | 1 |
| 2 | 0 | 0 |
| 2 | 1 | 1 |
| 2 | 2 | 2 |

a fifth digital logic element for carrying out a logical operation, the element having a first input (A), a second input (B), and one output (C), said logical operation being substantially defined by the following table:

| Input A | Input B | Output C |
|---|---|---|
| 0 | 0 | 0 |
| 0 | 1 | 1 |
| 0 | 2 | 2 |
| 1 | 0 | 1 |
| 1 | 1 | 1 |
| 1 | 2 | 1 |
| 2 | 0 | 2 |
| 2 | 1 | 1 |
| 2 | 2 | 2 |

a sixth digital logic element for carrying out a logical operation, the element having a first input (A), a second input (B), a third input (Carryᵢₙ), a first output (Sum), and a second output (Carryₒᵤₜ), said logical operation being substantially defined by the following table:

| Carryᵢₙ | Input A | Input B | Sum | Carryₒᵤₜ |
|---|---|---|---|---|
| 0 | 0 | 0 | 0 | 0 |
| 0 | 0 | 1 | 1 | 0 |
| 0 | 0 | 2 | 2 | 0 |
| 0 | 1 | 0 | 1 | 0 |
| 0 | 1 | 1 | 2 | 0 |
| 0 | 1 | 2 | 0 | 1 |
| Carryᵢₙ | Input A | Input B | Sum | Carryₒᵤₜ |
|---|---|---|---|---|
| 0 | 2 | 0 | 2 | 0 |
| 0 | 2 | 1 | 0 | 1 |
| 0 | 2 | 2 | 1 | 1 |
| 1 | 0 | 0 | 1 | 0 |
| 1 | 0 | 1 | 2 | 0 |
| 1 | 0 | 2 | 0 | 1 |
| 1 | 1 | 0 | 2 | 0 |
| 1 | 1 | 1 | 0 | 1 |
| 1 | 1 | 2 | 1 | 1 |
| 1 | 2 | 0 | 0 | 1 |
| 1 | 2 | 1 | 1 | 1 |
| 1 | 2 | 2 | 2 | 1 |
| 2 | 0 | 0 | 2 | 0 |
| 2 | 0 | 1 | 0 | 1 |
| 2 | 0 | 2 | 1 | 1 |
| 2 | 1 | 0 | 0 | 1 |
| 2 | 1 | 1 | 1 | 1 |
| 2 | 1 | 2 | 2 | 1 |
| 2 | 2 | 0 | 1 | 1 |
| 2 | 2 | 1 | 2 | 1 |
| 2 | 2 | 2 | 0 | 2 |

a seventh digital logic element for carrying out a logical operation, the element having a first input (A), a second input (B), and an output (C), said logical operation being substantially defined by the following table:

| Input A | Input B | Output C |
|---|---|---|
| 0 | 0 | 2 |
| 0 | 1 | 0 |
| 0 | 2 | 1 |
| 1 | 0 | 0 |
| 1 | 1 | 0 |
| 1 | 2 | 1 |
| 2 | 0 | 1 |
| 2 | 1 | 1 |
| 2 | 2 | 1 |

an eighth digital logic element for carrying out a logical operation, the element having a first input (A), a second input (B), a third input (C), a first output (D), a second output (E), and a third output (F), said logical operation being substantially defined by the following table:

| | | | Previous | Next |
|---|---|---|---|---|
| | | | Outputs | Outputs |
| Input A | Input B | Input C | (D, E, F) | (D, E, F) |
| 0 | 0 | 0 | (0, 1, 2) | (0, 1, 2) |
| 0 | 0 | 0 | (1, 2, 0) | (1, 2, 0) |
| 0 | 0 | 0 | (2, 0, 1) | (2, 0, 1) |
| 0 | 0 | 1 | (0, 1, 2) | (0, 1, 2) |
| 0 | 0 | 1 | (1, 2, 0) | (1, 2, 0) |
| 0 | 0 | 1 | (2, 0, 1) | (0, 1, 2) |
| 0 | 0 | 2 | | (1, 2, 0) |
| 0 | 1 | 0 | (0, 1, 2) | (0, 1, 2) |
| | | | Previous | Next |
|---|---|---|---|---|
| | | | Outputs | Outputs |
| Input A | Input B | Input C | (D, E, F) | (D, E, F) |
| 0 | 1 | 0 | (1, 2, 0) | (2, 0, 1) |
| 0 | 1 | 0 | (2, 0, 1) | (2, 0, 1) |
| 0 | 1 | 1 | | (0, 1, 2) |
| 0 | 1 | 2 | | (1, 0, 0) |
| 0 | 2 | 0 | | (0, 1, 2) |
| 0 | 2 | 1 | | (0, 1, 2) |
| 0 | 2 | 2 | | (1, 1, 0) |
| 1 | 0 | 0 | (0, 1, 2) | (1, 2, 0) |
| 1 | 0 | 0 | (1, 2, 0) | (1, 2, 0) |
| 1 | 0 | 0 | (2, 0, 1) | (2, 0, 1) |
| 1 | 0 | 1 | | (1, 2, 0) |
| 1 | 0 | 2 | | (1, 2, 0) |
| 1 | 1 | 0 | | (2, 0, 1) |
| 1 | 1 | 1 | | (0, 0, 0) |
| 1 | 1 | 2 | | (1, 0, 0) |
| 1 | 2 | 0 | | (0, 1, 0) |
| 1 | 2 | 1 | | (0, 1, 0) |
| 1 | 2 | 2 | | (1, 1, 0) |
| 2 | 0 | 0 | | (2, 0, 1) |
| 2 | 0 | 1 | | (0, 0, 1) |
| 2 | 0 | 2 | | (1, 0, 1) |
| 2 | 1 | 0 | | (2, 0, 1) |
| | | | Previous | Next |
|---|---|---|---|---|
| | | | Outputs | Outputs |
| Input A | Input B | Input C | (D, E, F) | (D, E, F) |
| 2 | 1 | 1 | | (0, 0, 1) |
| 2 | 1 | 2 | | (1, 0, 1) |
| 2 | 2 | 0 | | (0, 1, 1) |
| 2 | 2 | 1 | | (0, 1, 1) |
| 2 | 2 | 2 | | (1, 1, 1) |

a ninth digital logic element for carrying out a logical operation, the element having a first input (A), a second input (Clock), and one output (Out₁), said logical operation being substantially defined by the following table:

| Input A | Clock | Out₁ |
|---|---|---|
| 0 | Trigger | 0 |
| 1 | Trigger | 1 |
| 2 | Trigger | 2 |
| Any value | 0 | Unchanged |

a tenth digital logic element for carrying out a logical operation, the element having a first input (A), a second input (Clock), a third input (Set₀), a fourth input (Set₁), a fifth input (Set₂), a first output (Out₁), a second output (Out₂), and a third output (Out₃), wherein said second input repetitively undergoes a cycle comprising a first and a second transition, and wherein said tenth logical operation is substantially defined by the following table:

| Input A | Clock | Out₁ | Out₂ | Out₃ |
|---|---|---|---|---|
| 0 | First | 2 | 0 | 1 |
| | transition | | | |
| 1 | First | 0 | 1 | 2 |
| | transition | | | |
| 2 | First | 1 | 2 | 0 |
| | transition | | | |
| Any value | 0 | Unchanged | Unchanged | Unchanged |

and wherein the value of the outputs can be set while the clock is at 0 by applying signals at Set₀, Set₁, and Set₂, substantially according to the following table:

| Input A | Clock | Set₀ | Set₁ | Set₂ | Out₁ | Out₂ | Out₃ |
|---|---|---|---|---|---|---|---|
| X | 0 | 2 | 0 | 0 | 2 | 0 | 1 |
| X | 0 | 0 | 2 | 0 | 0 | 1 | 2 |
| X | 0 | 0 | 0 | 2 | 1 | 2 | 0; |

and, an eleventh digital logic element for carrying out a logical operation, the element having one input (A) and one output (B), said logical operation being substantially defined by the following table:

| Input A | Output B |
|---|---|
| 0 | 1 |
| 1 | 2 |
| 2 | 0 |

51. A digital logic circuit according to claim 50, for carrying out a nineteenth logical operation, being connectable to provide a multi-digit full adder.

52. A digital logic circuit according to claim 51, said circuit comprising a plurality of said sixth digital logic elements chained together, wherein said elements are operable as full adders, and wherein the Carryᵢₙ input of the first sixth digital logic element is connected to the 0 logic level, and the Carryᵢₙ input of each additional element is the Carryₒᵤₜ output of the element preceding said element.

53. A digital logic circuit according to claim 50, for carrying out a twentieth logical operation, being connectable to provide an SR flip-flop.

54. A digital logic circuit according to claim 53, the circuit having a first input (A), a second input (B), a third input (C), a first output (D), a second output (E), and a third output (F), and further comprising a first, a second, and a third seventh digital logic elements, the elements being connected as follows:
the inputs to the first seventh digital logic element being input A and the output of said third logic element;
the inputs to the second seventh digital logic element being input B and the output of said first logic element;
the inputs to the third seventh digital logic element being input C and the output of said second logic element; and,
the circuit outputs being the outputs of said three digital logic elements.

55. A digital logic circuit according to claim 50, for carrying out a twenty first logical operation, being connectable to provide a clocked SR flip-flop.

56. A digital logic circuit according to claim 55, the circuit having a first input (A), a second input (B), a third input (C), a fourth input (Clock), a first output (Q1), a second output (Q2), and a third output (Q3), wherein a clock signal varying between a first and a second logic state is applicable to said fourth input, said circuit further comprising a first, a second, and a third second digital logic element and one eighth digital logic element, the elements being connected within the circuit as follows:
the inputs to the first second digital logic element being input A and the clock input;
the inputs to the second logic element being input B and the clock input;
the inputs to the third second logic element being input C and the clock input;
the inputs to the eighth digital logic element being the outputs of the three second logic elements; and,
the outputs of the eighth digital logic element being the circuit outputs, Q1, Q2, and Q3.

57. A digital logic circuit according to claim 50, for carrying out a twenty second logical operation, being connectable to provide a multi-digit asynchronous counter.

58. A digital logic circuit according to claim 57, comprising a plurality of tenth digital logic elements chained together, having a first input (Clock), a second input (Reset), and one output for each of said elements, the clock signal being variable between a first and a second logic state, and said elements being connected together as follows:
the Set₀ inputs of said elements being connected together to provide the reset input of the logic circuit;
the Set₁ and Set₂ inputs of said elements being connected together and set to 0; the Clock input of said logic circuit being the Clock input of the first of said elements;
the Out₃ output of each of said element being connected to its A input;
the Out₂ outputs of each of said elements being connected to the clock input of the following element; and,
the outputs of said logic circuit being the Out2 outputs of said elements.

59. A method for designing a digital logic circuit to implement a truth table, relating the state of at least one input to the state of an output, each input and each output being capable of assuming at least three logic states, comprising a first state (0), a second state (1), and a third state (2) , the method comprising:
providing a predetermined truth table having a plurality of rows relating input states to corresponding output states;
identifying each line of the table in which the output state is non-zero;
expressing each thus identified line of the table as a combination of AND and NOT operations on the inputs, so that for the given input values the result of the said operations is the value of the output as given in said table, and for all other input values the result is zero; and,
using said corresponding outputs as inputs to a multi-input OR operation, wherein if all inputs are 0 the output is 0, if the inputs contain 1's but no 2's the output is 1, and if the inputs contain 2's the output is 2, thereby producing a first relationship between said input states and said output states.

60. A method for designing a digital logic circuit to implement a truth table according to claim 59, further comprising:
reducing the number of inputs and variables in said first relationship by use of at least one of the following logical expressions:
X+X=X,
X*X=X,
X+Y=Y+X,
X*Y=Y*X,
X+0=X,
X*1=X,
X*0=0,
X+2=2,
X*(Y+Z)=X*Y+X*Z,
X*(Y*Z)=(X*Y)*Z,
X+(Y+Z)=(X+Y)+Z,
X*Y+X=X*(Y+1),
X#+Y#+Z# . . . =(X*Y*Z* . . . )#, and
X##*Y##Z## . . . =(X+Y+Z+ . . . )##,
thereby producing a second reduced relationship between said input states and said output states.

61. A method for designing a digital logic circuit to implement a truth table according to claim 59, further comprising:
reducing the number of inputs and variables in said first relationship by use of at least one of the following logical expressions:
X+X=X,
X*X=X,
X+Y=Y+X,
X*Y=Y*X,
X+0=X,
X*2=X,
X*0=0,
X+1=1,
X*(Y+Z)=X*Y+X*Z,
X*(Y*Z)=(X*Y)*Z,
X+(Y+Z)=(X+Y)+Z,
X*Y+X=X*(Y+2),
X##+Y##+Z## . . . (X*Y*Z* . . . )##, and
X#*Y#*Z# . . . =(X+Y+Z+ . . . )#,
thereby producing a second reduced relationship between said input states and said output states.

62. A method for designing a digital logic circuit to implement a truth table according to claim 59, wherein the step of expressing each said line of the table as a combination of AND and NOT operations on the inputs further comprises:
performing an idXY operation on each said input, wherein X is the input value and Y is the predetermined non-zero output value; wherein the idXY operation is given below:
id01(A)=(2*A)##,
id02(A)=(A#)*(A##),
id11(A)=(2*A#)##,
id12(A)=A*(A##),
id21(A)=(2*A##)##, and
id22(A)=A* A#; and,
using the results of these expressions as inputs to a multi-input AND operation, wherein if any inputs are zero the output is zero, if all inputs are 1 the result is 1, and if all inputs are 2 the output is 2.

63. A method for building a digital logic circuit to implement a truth table, relating the state of at least one input to the state of an output, each input and each output being capable of assuming at least three logic states, comprising a first state (0), a second state (1), and a third state (2), the method comprising:
providing a predetermined truth table having a plurality of rows relating input states to corresponding output states;
identifying each line of the table in which the output state is non-zero;
expressing each thus identified line of the table as a combination of AND and NOT operations on the inputs, so that for the given input values the result of the said operations is the value of the output as given in said table, and for all other input values the result is zero;
using said corresponding outputs as inputs to a multi-input OR operation, wherein if all inputs are 0 the output is 0, if the inputs contain l's but no 2's the output is 1, and if the inputs contain 2's the output is 2, thereby producing a first relationship between said input states and said output states; and,
building a 3-state logic circuit by connecting 3-state logic AND, OR, and NOT gates according to said first relationship.

64. A method for building a digital logic circuit to implement a truth table, relating the state of at least one input to the state of an output, each input and each output being capable of assuming at least three logic states, comprising a first state (0), a second state (1), and a third state (2), the method comprising:
providing a predetermined truth table having a plurality of rows relating input states to corresponding output states;
identifying each line of the table in which the output state is non-zero; expressing each thus identified line of the table as a combination of AND and NOT operations on the inputs, so that for the given input values the result of the said operations is the value of the output as given in said table, and for all other input values the result is zero;
using said corresponding outputs as inputs to a multi-input OR operation, wherein if all inputs are 0 the output is 0, if the inputs contain 1's but no 2's the output is 1, and if the inputs contain 2's the output is 2, thereby producing a first relationship between said input states and said output states;
reducing the number of inputs and variable in the resulting expression by use of at least one of the following logical expressions:
X+X=X,
X*X=X,
X+Y=Y+X,
X*Y=Y*X,
X+0=X,
X*1=X,
X*0=0,
X+2=2,
X*(Y+Z)=X*Y+X*Z,
X*(Y*Z)=(X*Y)*Z,
X+(Y+Z)=(X+Y)+Z,
X*(Y+1)=X*Y+X,
(X*Y*Z* . . . )#=X#+Y#+Z# . . . , and
(X+Y+Z+ . . . )##=X##*Y##*Z## . . . ,
thereby producing a second reduced relationship between said input states and said output states; and,
building a 3-state logic circuit by connecting 3-state logic AND, OR, and NOT gates according to said second relationship.

65. A method for building a digital logic circuit to implement a truth table according to claim 64, wherein the step of expressing each said line of the table as a combination of AND and NOT operations on the inputs further comprises:
performing an idXY operation on each said input, wherein X is the input value and Y is the predetermined non-zero output value; wherein the idXY operation is given below:
id01(A)=(2*A)##,
id02(A)=(A#)*(A##),
id11(A)=(2*A#)##,
id12(A)=A*(A##),
id21(A)=(2*A##)##, and
id22(A)=A*A# and,
using the results of these expressions as inputs to a multi-input AND operation, wherein if any inputs are zero the output is zero, if all inputs are 1 the result is 1, and if all inputs are 2 the output is 2.

66. A method for automatically designing a digital logic circuit to implement a truth table, relating the state of at least one input to the state of an output, each input and each output being capable of assuming at least three logic states, comprising a first state (0), a second state (1), and a third state (2), comprising:
providing a predetermined truth table having a plurality of rows relating input states to corresponding output states;
automatically designing a circuit by:
identifying each line of the table in which the output state is non-zero;
expressing each thus identified line of the table as a combination of AND and NOT operations on the inputs, so that for the given input values the result of the said operations is the value of the output as given in said table, and for all other input values the result is zero;
using said corresponding outputs as inputs to a multi-input OR operation, wherein if all inputs are 0 the output is 0, if the inputs contain 1's but no 2's the output is 1, and if the inputs contain 2's the output is 2, thereby producing a first relationship between said input states and said output states; and;
reducing the number of inputs and variable in the resulting expression by use of at least one of the following logical expressions:
X+X=X,
X*X=X,
X+Y=Y+X,
X*Y=Y*X,
X+0=X,
X*1=X,
X*0=0,
X+2=2,
X*(Y+Z)=X*Y+X*Z,
X*(Y*Z)=(X*Y)*Z,
X+(Y+Z)=(X+Y)+Z,
X*Y+X=X*(Y+1),
X#+Y# . . . =(X*Y*Z* . . . )#, and
X##Y##Z# . . . =(X+Y+Z+ . . . )##,
thereby producing a second reduced relationship between said input states and said output states;
simulating the circuit designated by said second relationship; and, verifying that for every combination of inputs the circuit provides the specified output.

67. A method of building non-binary digital circuitry, comprising the steps of:
selecting a base for non-binary digital operation;
defining each of AND, and OR operations in said base;
defining a cyclic NOT operation in said base, wherein if the input to said NOT operation is cyclic the output is cyclic;
testing the system to determine if it possesses at least one of a group of characteristics comprising:
possession of a zero member,
possession of a one member,
obeys the Idempotent Law,
obeys the Commutative Law, and
obeys the DeMorgan Laws;
if the system does not possess at least one of the characteristics, then redefining said operations until a fit is achieved; and,
building at least one logic gate according to the defined operations.

68. A method of building non-binary digital circuitry according to claim 67, where the step of testing the system to determine if it possesses one of a group of characteristics further comprises the step of:
testing said AND, OR, and NOT operations to determine whether they fit at least one of a group of identities comprising:
X+X=X,
X*X=X,
X+Y=Y+X,
X*Y=Y*X,
X+0=X,
X*1=X,
X*0=0,and
X+2=2.

69. A method of building non-binary digital circuitry according to claim 67, further comprising:
specifying a truth table that provides circuit output values for every combination of input values;
expressing said truth table in terms of said AND, OR, and NOT operations to form an expressed truth table;
reducing said expressed truth table using said characteristics; and,
building said circuitry using said reduced expressed truth table and said gates.

70. A method of building non-binary digital circuitry according to claim 68, wherein the group of identities further comprises:
X#+Y#+Z# . . . =(X*Y*Z . . . )#, and
X##*Y##+Z## . . . =(X+Y+Z . . . )##.

71. A method of building non-binary digital circuitry according to claim 68, wherein the group of identities further comprises:
X*(Y+Z)=X*Y+X*Z.

72. A method of building non-binary digital circuitry according to claim 68, wherein the group of identities further comprises:
X*(Y*Z)=(X*Y)*Z, and
X+(Y+Z)=(X+Y)+Z.

73. A method of building non-binary digital circuitry according to claim 67, wherein the base of the digital operation is three.

74. A method of building non-binary digital circuitry according to claim 67, wherein the base of the digital operation is greater than three.

75. A method of building non-binary digital circuitry according to claim 69, wherein the step of expressing said predetermined truth table in terms of said operations to form an expressed truth table further comprises:
defining an idXY operation, wherein X and Y represent logic states under the base for digital operation, and wherein the output is logic state Y if the input is logic state X, and the output is logic state 0 if the input is not logic state X;
identifying every combination of inputs which yields a non-zero output in said truth table;
for each line of the truth table thus identified, expressing said line to form an expressed line by expressing each line as a series of idXY operations on each expression and performing a multi-input AND operation between all said idXY expressions; and,
performing a multi-input OR operation between all said expressed lines of the truth table.

76. A method for building a digital logic circuit to implement a truth table, relating the state of at least one input to the state of an output, each input and each output being capable of assuming at least three logic states, comprising a first state (0), a second state (1), and a third state (2), the method comprising:
providing a predetermined truth table having a plurality of rows relating input states to corresponding output states;
identifying each line of the table in which the output state is non-zero;
expressing each thus identified line of the table as a combination of AND and NOT operations on the inputs, so that for the given input values the result of the said operations is the value of the output as given in said table, and for all other input values the result is zero;
using said corresponding outputs as inputs to a multi-input OR operation, wherein if all inputs are 0 the output is 0, if the inputs contain 1's but no 2's the output is 1, and if the inputs contain 2's the output is 2, thereby producing a first relationship between said input states and said output states;
reducing the number of inputs and variable in the resulting expression by use of at least one of the following characteristics:
possession of a zero member,
possession of a one member,
the Idempotent Law,
the Associative Law,
the Identity Laws,
the Dominance Laws,
the Complement Laws,
the Distributive Law,
the Commutative Law, and
the DeMorgan Laws,
thereby producing a second reduced relationship between said input states and said output states; and,
building a 3-state logic circuit by connecting 3-state logic AND, OR, and NOT gates according to said second relationship.

77. A method for automatically designing a digital logic circuit to implement a truth table, relating the state of at least one input to the state of an output, each input and each output being capable of assuming at least three logic states, comprising a first state (0), a second state (1), and a third state (2), comprising:
providing a predetermined truth table having a plurality of rows relating input states to corresponding output states;
automatically designing a circuit by:
identifying each line of the table in which the output state is non-zero;
expressing each thus identified line of the table as a combination of AND and NOT operations on the inputs, so that for the given input values the result of the said operations is the value of the output as given in said table, and for all other input values the result is zero;
using said corresponding outputs as inputs to a multi-input OR operation, wherein if all inputs are 0 the output is 0, if the inputs contain l's but no 2's the output is 1, and if the inputs contain 2's the output is 2, thereby producing a first relationship between said input states and said output states; and;
reducing the number of inputs and variable in the resulting expression by use of at least one of the following characteristics:
possession of a zero member,
possession of a one member,
the Idempotent Law,
the Associative Law,
the Identity Laws,
the Dominance Laws,
the Complement Laws,
the Distributive Law,
the Commutative Law, and
the DeMorgan Laws,
thereby producing a second reduced relationship between said input states and said output states;
simulating the circuit designated by said second relationship; and,
verifying that for every combination of inputs the circuit provides the specified output.
